(19) United States
(12) Patent Application Publication
(10) Pub. No.: US 2024/0027585 A1
(43) Pub. Date: Jan. 25, 2024

(54) LIGHT RECEIVING DEVICE, CONTROL METHOD OF LIGHT RECEIVING DEVICE, AND RANGING SYSTEM

(71) Applicant: SONY SEMICONDUCTOR SOLUTIONS CORPORATION, KANAGAWA (JP)

(72) Inventors: YUKI MORIKAWA, KANAGAWA (JP); YUSUKE IKEDA, KANAGAWA (JP)

(21) Appl. No.: 18/250,263

(22) PCT Filed: Oct. 19, 2021
(86) PCT No.: PCT/JP2021/038533

§ 371 Date: Apr. 24, 2023

(30) Foreign Application Priority Data
Oct. 30, 2020 (JP) 2020-182883

(51) Int. Cl. G01S 7/481; G01S 7/4863; G01S 17/14; H01L 31/107

(52) U.S. Cl. CPC G01S 7/4817; G01S 7/4816; G01S 7/4863; G01S 17/14; H01L 31/107; G01S 17/931

(57) ABSTRACT

A light receiving device according to an embodiment includes: a light receiving element (1000) using an SPAD; a current source (1001) that supplies a recharge current to the SPAD; a detection section (1002) that detects a voltage based on a current, inverts an output signal in a case where a voltage value of the detected voltage exceeds a threshold value, shapes the inverted output signal into a pulse signal, and outputs the pulse signal; a plurality of counters (201(1) to 201(N)) that each counts the pulse signal output from the detection section; and a distribution section (1101) that selects a target counter to which the pulse signal is to be supplied from the plurality of counters, in which distribution section selects the target counter by a plurality of control signals corresponding to the plurality of counters on a one-to-one basis, the plurality of control signals including a state of simultaneously selecting two or more counters among the plurality of counters.

### FIELD

The present disclosure relates to a light receiving device, a control method of the light receiving device, and a ranging system.

### BACKGROUND

There is known a ranging method called Time of Flight (ToF) in which a distance to a measurement object is measured on the basis of time from emission of light from a light source to reception of reflection light of the light reflected by the measurement object by a light receiving section. Among the ranging methods using ToF, in the indirect ToF method, for example, light source light (for example, laser light in an infrared region) modulated by pulse width modulation (PWM) is emitted to a measurement object, reflection light thereof is received by a light receiving element, and ranging with respect to the measurement object is performed on the basis of a phase difference in the received reflection light.

### CITATION LIST

### Non Patent Literature

Non Patent Literature 1: Rocca, Francesco & Mai, Hanning & Hutchings, Sam & Abbas, Tarek & Tsiamis, Andreas & Lomax, Peter & Gyongy, Istvan & Dutton, Neale & Henderson, Robert, “A 128×128 SPAD Dynamic Vision-Triggered Time of Flight Imager.”, (Poland), IEEE 45th European Solid State Circuits Conference, September 2019, p. 93-p. 96

### SUMMARY

### Technical Problem

In the indirect ToF method, reflection light is received at a plurality of phases, and a phase difference of the received reflection light is obtained. Conventionally, at the time of ranging by the indirect ToF method, it is necessary to sequentially execute emission of the light source light and reception of the reflection light for each phase, which is not efficient.

An object of the present disclosure is to provide a light receiving device, a control method of the light receiving device, and a ranging system capable of more efficiently performing ranging.

### Solution to Problem

For solving the problem described above, a light receiving device according to one aspect of the present disclosure has a light receiving element in which avalanche multiplication occurs in response to a photon incident in a state of being charged to a predetermined potential to cause a current to flow, the light receiving element returning to the state by a recharge current; a current source that supplies the recharge current; a detection section that detects a voltage based on the current, inverts an output signal in a case where a voltage value of the detected voltage exceeds a threshold value, shapes the inverted output signal into a pulse signal, and outputs the pulse signal; a plurality of counters that each count the pulse signal output from the detection section; and a distribution section that selects a target counter to which the pulse signal is to be supplied from among the plurality of counters, wherein the distribution section selects the target counter by a plurality of control signals corresponding to the plurality of counters on a one-to-one basis, the plurality of control signals including a state of simultaneously selecting two or more counters among the plurality of counters.

### BRIEF DESCRIPTION OF DRAWINGS

FIG. 1 is a block diagram depicting a configuration of an example of an electronic device using a ranging device applicable to each embodiment.

FIG. 2 is a schematic diagram for describing an example of a basic measurement method of indirect ToF.

FIG. 3A is a schematic diagram depicting an example of a modulation code by Hamiltonian encoding.

FIG. 3B is a diagram for describing a repetition period and a frame period.

FIG. 4 is a cross-sectional view depicting an example of a structure of a dual gate PD according to related technology.

FIG. 5 is a schematic diagram depicting an example in which a dual gate PD is applied to a modulation code by Hamiltonian encoding.

FIG. 6 is a block diagram depicting an example of a basic configuration of a ranging device 100 applicable to each embodiment in more detail.

FIG. 7A is a diagram depicting a basic configuration example of a pixel circuit applicable to each embodiment.

FIG. 7B is a schematic graph depicting an example of a signal in a pixel circuit applicable to each embodiment.

FIG. 8 is a diagram depicting an exemplary structure of a part of a pixel circuit 10 formed on a sensor chip applicable to each embodiment.

FIG. 9 is a diagram depicting an example of a light receiving circuit according to a first embodiment.

FIG. 10 is a schematic diagram for describing an example of a measurement method according to the first embodiment.

FIG. 11A is a graph for describing an effect of a ranging method according to the first embodiment.

FIG. 11B is a graph for describing an effect of a ranging method according to the first embodiment.

FIG. 12 is a diagram depicting an example of a modulation code by Hamiltonian encoding in a case where order k=5, which is applicable to the first embodiment.

FIG. 13A is a diagram for describing binning according to a first modification of the first embodiment.

FIG. 13B is a diagram for describing binning according to the first modification of the first embodiment.

FIG. 14A is a diagram for describing binning according to a second modification of the first embodiment.

FIG. 14B is a diagram for describing binning according to the second modification of the first embodiment.

FIG. 15A is a diagram depicting an example of modulation patterns according to a third modification of the first embodiment.

FIG. 15B is a diagram depicting an example of modulation patterns according to the third modification of the first embodiment.

FIG. 16 is a diagram depicting a basic configuration example in a case where luminance is detected using an SPAD.

FIG. 17A is a diagram for describing a configuration example in a case where luminance detection and ranging are both used according to a second embodiment.

FIG. 17B is a diagram for describing a configuration example in a case where luminance detection and ranging according to the second embodiment are both used.

FIG. 18A is a diagram for more specifically describing a distribution and switching circuit applicable to the first configuration example according to the second embodiment.

FIG. 18B is a diagram for more specifically describing the distribution and switching circuit applicable to the first configuration example according to the second embodiment.

FIG. 18C is a diagram for more specifically describing the distribution and switching circuit applicable to the first configuration example according to the second embodiment.

FIG. 19A is a diagram for describing a second configuration example in a case where luminance detection and ranging according to the second embodiment are both used.

FIG. 19B is a diagram depicting an example of a light receiving circuit according to the second configuration example according to the second embodiment.

FIG. 19C is a diagram depicting a configuration example of a distribution and switching circuit applicable to the second configuration example according to the second embodiment in more detail.

FIG. 20A is a diagram depicting an example of a light receiving circuit according to a third configuration example according to the second embodiment.

FIG. 20B is a diagram depicting an example of modulation patterns applicable to the third configuration example according to the second embodiment.

FIG. 21 is a schematic diagram depicting a first example of a device configuration according to a third embodiment.

FIG. 22 is a schematic diagram depicting a second example of the device configuration according to the third embodiment.

FIG. 23 is a schematic diagram depicting a third example of the device configuration according to the third embodiment.

FIG. 24 is a diagram depicting use examples in which a ranging device to which the first embodiment and the modifications thereof, the second embodiment, and the third embodiment can be applied according to a fifty fourth embodiment.

FIG. 25 is a block diagram depicting an example of schematic configuration of a vehicle control system as an example of a mobile body control system to which the technology according to the present disclosure can be applied.

FIG. 26 is a diagram depicting an example of installation positions of imaging sections.

### DESCRIPTION OF EMBODIMENTS

Hereinafter, embodiments of the present disclosure will be described in detail on the basis of the drawings. Note that in each of the following embodiments, the same parts are denoted by the same symbols, and redundant description will be omitted.

Hereinafter, embodiments of the present disclosure will be described in the following order.
1. Technology Applicable to Present Disclosure
1-1. Overview of Indirect ToF
1-2. Example of Measurement Method by Indirect ToF
1-2-1. Example of Basic Measurement Method
1-2-2. Example of Measurement Method to Which Hamiltonian Is Applied
1-3. About Related Technology
1-3-1. Example of Light Receiving Element of Related Technology
1-3-2. Example of Measurement Method in Which Hamiltonian Encoding Is Applied to Related Technology
2. First Embodiment of Present Disclosure
2-1. Configuration Example Applicable to First Embodiment
2-1-1. About Configuration Example of Ranging Device
2-1-2. About Light Receiving Element
2-2. Configuration Example According to First Embodiment
2-2-1. Example of Light Receiving Circuit
2-2-2. Example of Measurement Method
2-2-3. Exemplary Effects
2-2-4. Extension Example
2-3. First Modification of First Embodiment
2-4. Second Modification of First Embodiment
2-5. Third Modification of First Embodiment
3. Second Embodiment of Present Disclosure
3-1. Configuration Example According to Second Embodiment
3-1-1. Basic Configuration Example of Luminance Detection
3-1-2. First Configuration Example Using Both Luminance Detection and Ranging
3-1-3. Second Configuration Example Using Both Luminance Detection and Ranging
3-1-4. Third Configuration Example Using Both Luminance Detection and Ranging
4. Third Embodiment of Present Disclosure
4-1. First Example of Device Configuration According to Third Embodiment
4-2. Second Example of Device Configuration According to Third Embodiment
4-3. Third Example of Device Configuration According to Third Embodiment
5. Fourth Embodiment of Present Disclosure
5-1. Application Example of Technology of Present Disclosure
5-2. Application Example to Mobile Body

### 1. Technology Applicable to Present Disclosure

Prior to describing embodiments of the present disclosure, technology applicable to the present disclosure will be described to facilitate understanding.

The present disclosure is suitable for use in technology for performing ranging using light. Prior to the description of the embodiments of the present disclosure, the indirect time of flight (ToF) method will be described as one of ranging methods applicable to the embodiments in order to facilitate understanding. The indirect ToF method is technology for performing ranging, for example, light source light (for example, laser light in an infrared region) modulated by pulse width modulation (PWM) is emitted to a measurement object, reflection light thereof is received by a light receiving element, and performing ranging with respect to the measurement object on the basis of a phase difference in the received reflection light.

### 1-1. Overview of Indirect ToF

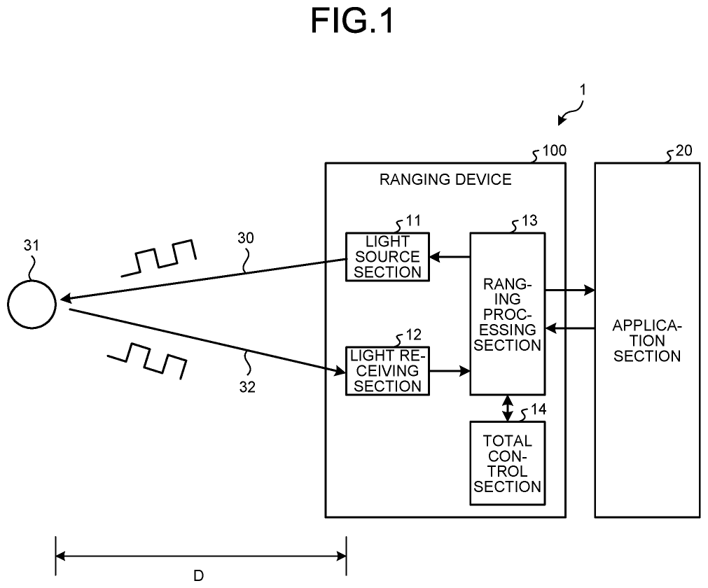

FIG. 1 is a block diagram depicting a configuration of an example of an electronic device using a ranging device applicable to each embodiment. In FIG. 1, an electronic device 1 includes a ranging device 100 and an application section 20. The application section 20 is implemented, for example, by a program operating on a central processing unit (CPU) and requests the ranging device 100 to execute ranging and receives distance information or the like which is a result of the ranging from the ranging device 100.

The ranging device 100 includes a light source section 11, a light receiving section 12, a ranging processing section 13, and a total control section 14. The total control section 14 includes, for example, a microprocessor and controls the overall operation of the ranging device 100. The total control section 14 performs, for example, control of the operation of the ranging processing section 13, generation of a basic clock signal used in the sections of the ranging device 100, and others.

The light source section 11 is configured as a light source device including, for example, a light emitting element that emits light having a wavelength in the infrared region and a drive circuit that drives the light emitting element to emit light. For example, a light emitting diode (LED) can also be adopted as the light emitting element included in the light source section 11. Without being limited thereto, a vertical cavity surface emitting laser (VCSEL) in which a plurality of light emitting elements is formed in an array can also be applied as the light emitting element included in the light source section 11. Hereinafter, unless otherwise specified, “for the light emitting element of the light source section 11 to emit light” will be described as “for the light source section 11 to emit light” or the like.

The light receiving section 12 includes, for example, a light receiving element capable of detecting light having a wavelength in the infrared region and a signal processing circuit that outputs a pixel signal corresponding to the light detected by the light receiving element. A photodiode (PD) or a single photon avalanche diode (SPAD) can be applied as the light receiving element included in the light receiving section 12. Hereinafter, unless otherwise specified, “for the light receiving element included in the light receiving section 12 to receive light” will be described as “for the light receiving section 12 to receive light” or the like. The SPAD will be described later.

The ranging processing section 13 executes ranging processing in the ranging device 100 in response to a ranging instruction from the application section 20, for example. For example, the ranging processing section 13 generates a light source control signal for driving the light source section 11 and supplies the light source control signal to the light source section 11. Furthermore, the ranging processing section 13 controls light reception by the light receiving section 12 in synchronization with a light source control signal supplied to the light source section 11. For example, the ranging processing section 13 generates an exposure control signal for controlling an exposure period in the light receiving section 12 in synchronization with the light source control signal and supplies the exposure control signal to the light receiving section 12. The light receiving section 12 outputs a valid pixel signal within the exposure period indicated by the exposure control signal.

The ranging processing section 13 calculates distance information on the basis of the pixel signal output from the light receiving section 12 in response to light reception. Furthermore, the ranging processing section 13 can also generate predetermined image information on the basis of the pixel signal. The ranging processing section 13 passes the distance information and the image information calculated and generated on the basis of the pixel signal to the application section 20.

In such a configuration, the ranging processing section 13 generates the light source control signal for driving the light source section 11 in accordance with an instruction to execute ranging from the application section 20, for example, and supplies the light source control signal to the light source section 11. Incidentally, the ranging processing section 13 generates a light source control signal modulated into a rectangular wave having a predetermined duty by PWM and supplies the light source control signal to the light source section 11. At the same time, the ranging processing section 13 controls light reception by the light receiving section 12 on the basis of the exposure control signal synchronized with the light source control signal.

In the ranging device 100, the light source section 11 blinks and emits light at a predetermined duty in response to the light source control signal generated by the ranging processing section 13. The light emitted from the light source section 11 is emitted from the light source section 11 as emission light 30. The emission light 30 is reflected by, for example, a measurement object 31 and received by the light receiving section 12 as reflection light 32. The light receiving section 12 supplies a pixel signal corresponding to reception of the reflection light 32 to the ranging processing section 13. Note that, in practice, the light receiving section 12 receives surrounding ambient light in addition to the reflection light 32, and the pixel signal includes a component of the ambient light together with a component of the reflection light 32.

The ranging processing section 13 executes light reception by the light receiving section 12 a plurality of times in different phases. The ranging processing section 13 calculates a distance D to the measurement object on the basis of a difference in pixel signals by light reception at different phases. Furthermore, the ranging processing section 13 calculates first image information obtained by extracting the component of the reflection light 32 on the basis of the difference between the pixel signals and second image information including the component of the reflection light 32 and the component of the ambient light. Hereinafter, the first image information is referred to as direct reflection light information, and the second image information is referred to as RAW image information.

### 1-2. Example of Measurement Method by Indirect ToF

Next, an example of a measurement method using indirect ToF will be described.

### 1-2-1. Example of Basic Measurement Method

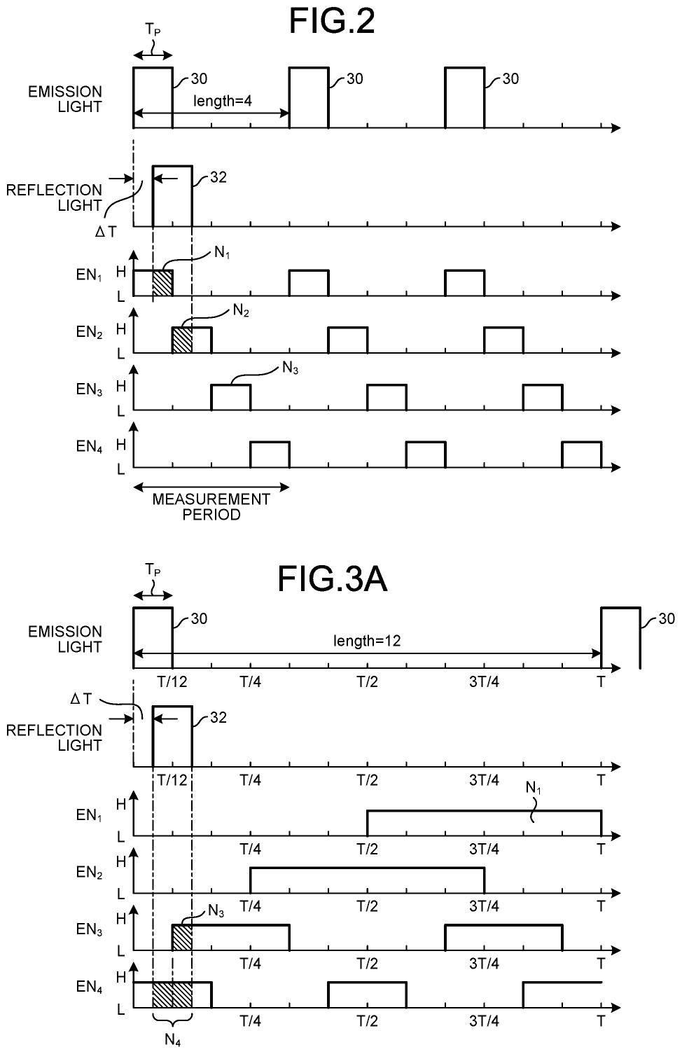

FIG. 2 is a schematic diagram for describing an example of a basic measurement method of indirect ToF. In FIG. 2, the elapse of time is depicted in the left direction, and the upper side depicts an example of the emission light 30 by the light source section 11 and an example of the reflection light 32 in which the emission light 30 is reflected by the measurement object 31 and reaches the light receiving section 12.

Furthermore, the lower side of FIG. 2 depicts an example of an enable signal EN for the ranging processing section 13 to implement a measurement pattern based on a modulation code that specifies a measurement period for measuring the amount of light received by the light receiving section 12. The enable signal EN activates the measurement of the amount of light received by the light receiving section 12 in a high state (H) and deactivates the measurement in a low state (L). That is, a measurement pattern is configured by a combination of the high state and the low state of the enable signal, and a period during which the enable signal EN is in the high state is a measurement period of the amount of light received by the light receiving section 12.

Furthermore, in FIG. 2, the light source section 11 emits the emission light 30 for a period of time T_{P}. Hereinafter, the time T_{P} is set as a unit time, and emission of the emission light 30 by the light source section 11 and light reception by the light receiving section 12 are controlled in accordance with a clock corresponding to the unit time. Hereinafter, the time T_{P} is referred to as a unit time T_{P} as appropriate.

The modulation code depicted in FIG. 2 includes four measurement patterns in which the phase of the measurement period is shifted by being shifted by each unit time with respect to the origin (left end of the drawing). The lower side of FIG. 2 is an example in which the measurement pattern is divided into four measurement patterns by enable signals EN₁ to EN₄ in accordance with the modulation code. In addition, in the example of FIG. 2, each measurement period in which measurement of the amount of light is active is set to have a length equal to the unit time. Meanwhile, a distance corresponding to the unit time is defined as a unit distance (c×T_{P}/2).

Hereinafter, the enable signals EN for implementing first, second, . . . , and Nth phases included in the modulation code are referred to as enable signals EN₁, EN₂, . . . , and EN_{N}, respectively. Furthermore, a measurement period during which the enable signal ENₓ enters the high state and measurement of the amount of light is active is described as “measurement period by an enable signal ENₓ” as appropriate.

Here, as depicted in the upper side of FIG. 2, a case where the reflection light 32 reaches the light receiving section 12 at timing delayed from the emission light 30 by a time ΔT will be examined. In this case, if time ΔT<time T_{P}, the light receiving section 12 receives the reflection light 32 over measurement periods by the enable signals EN₁ and EN₂. It is based on the premise that the light receiving section 12 measures the reflection light 32 as the amount of light N₁ in the measurement period by the enable signal EN₁ and the amount of light N₂ in the measurement period by the enable signal EN₂. The amount of light N₁+N₂ obtained by adding the amounts of light N₁ and N₂ is the amount of the reflection light 32 that has reached the light receiving section 12 after the emission light 30 has been reflected by the measurement object 31.

In this case, the distance D from the ranging device 100 to the measurement object 31 is calculated by Equation (1). Note that, in Equation (1), a constant c represents the speed of light (2.9979×10⁸ [m/sec]).

$$D = \frac{1}{2} c Δ T \qquad ( 1 )$$

The time ΔT is calculated by Equation (2) using the ratio between the amount of light N₁ and the amount of light N₂.

$$Δ T = {T}_{p} \frac{{N}_{2}}{{N}_{1} + {N}_{2}} \qquad ( 2 )$$

From the Equations (1) and (2), the distance D is calculated by Equation (3).

$$D = \frac{1}{2} c {T}_{p} \frac{{N}_{2}}{{N}_{1} + {N}_{2}} \qquad ( 3 )$$

According to the ranging method depicted in FIG. 2, in a case where the distance D to the measurement object 31 is greater than the measurement period, that is, in a case where time corresponding to the distance D is longer than the measurement period, the measurement period of the reflection light 32 overlaps with or is included in a subsequent measurement period after the measurement period in which the emission light 30 has been emitted. Therefore, it is difficult to distinguish from the light reception in the previous measurement period, and aliasing occurs. Therefore, in the measurement method of FIG. 2, the upper limit of the distance that can be measured is four unit distances corresponding to the total length of temporally continuous measurement periods within one measurement period in the respective measurement patterns. The upper limit of the distance that can be measured due to aliasing is set as a return distance of length, and in the example of FIG. 2, the return distance is length=4.

Note that, by subtracting the amount of light N₃ in the measurement period by the enable signal EN₃, in which, for example, the reflection light 32 relating to the amount of lights N₁ and N₂ is not received, from each of the numerator and the denominator in the fractional part in the latter half of Equation (3), noise due to the ambient light can be canceled, and ranging with higher accuracy can be performed.

Furthermore, in a case where time ΔT>time T_{P}, the distance D can be obtained by, for example, using time nT_{P} which is n times T_{P} included in the time ΔT as an offset time α and adding the offset time α to the value obtained by the above-described Equation (3).

### 1-2-2. Example of Measurement Method to which Hamiltonian is Applied

According to the modulation code depicted in FIG. 2, the return distance of length=4 holds, and four unit distances are the upper limit of distance that can be measured for the measurement patterns by the four enable signals EN₁ to EN₄. Meanwhile, a modulation code capable of setting the upper limit of the distance that can be measured to a longer distance has been proposed. Here, as an example of such a modulation code capable of ranging with a longer distance, a code generally called Hamiltonian encoding will be described.

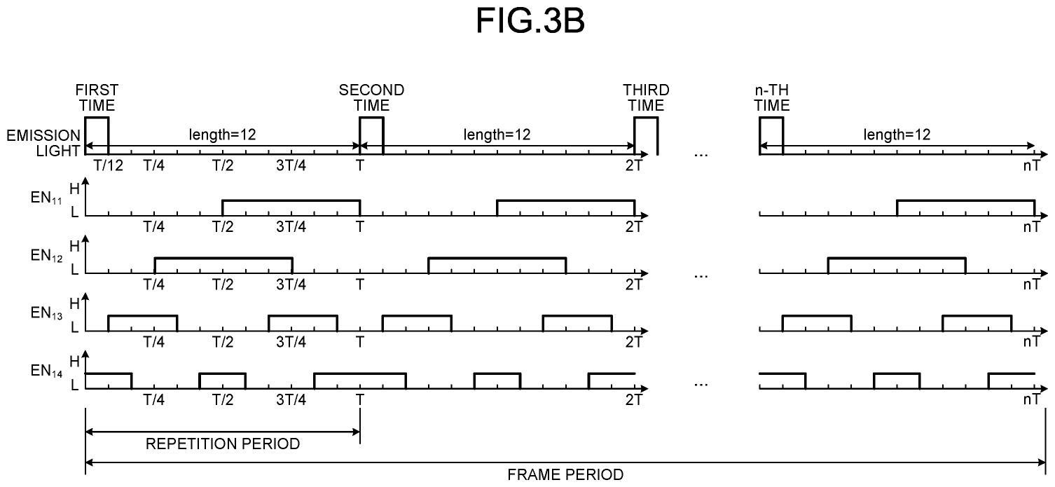

FIG. 3A is a schematic diagram depicting an example of a modulation code by Hamiltonian encoding. The modulation code depicted in FIG. 3A is an example in which the measurement pattern is distributed to four measurement patterns each having different phases in accordance with Hamiltonian encoding. In Hamiltonian encoding, each measurement pattern (clock pattern) is selected in such a manner that the return distance is the longest when a plurality of measurement patterns (clock patterns) each having different phases is arranged with the origins aligned.

More specifically, in Hamiltonian encoding, a measurement pattern (clock pattern) is determined so that the plurality of measurement patterns satisfies the following two conditions.

Condition (1)

The plurality of measurement patterns exclude a state in which all pieces of measurement are active or inactive in a unit time corresponding to each other. In the example of FIG. 3A, among the enable signals EN₁ to EN₄ indicating active or inactive state of the respective measurement patterns, at least one signal is in a high state and at least one signal is in a low state in each unit time.

Condition (2)

In each measurement pattern, the active and inactive states of measurement in a unit time corresponding to each other are caused to transition to an adjacent unit time in such a manner that the Hamming distance is “1.” For example, in a case where the state in which the measurement is active is denoted as “1” and the state in which the measurement is inactive is denoted as “0,” in the example of FIG. 3A, the states of the enable signals EN₁ to EN₄ indicating the active or inactive state of each of the measurement patterns are “0, 0, 0, 1” in the first unit time and “0, 0, 1, 1” in the next unit time, and it can be seen that the Hamming distance between the first unit time and the next unit time is “1.”

In the example of FIG. 3A, the enable signal EN₁ is set to a low state in a period of six unit times from the origin, a high state in a period of the next six unit times, and the enable signal EN₂ is set to a low state in a period of the first three unit times, a high state in a period of the next six unit times, and a low state in a period of the next three unit times. In addition, the enable signal EN₃ is set to, in a time series, a low state for one unit time, a high state for three unit times, a low state for four unit times, a high state for three unit times, and a low state for one unit time. Furthermore, the enable signal EN₄ is set to, in a time series, a high state for two unit times, a low state for three unit times, a high state for two unit times, a low state for three unit times, and a high state for two unit times.

The measurement patterns (clock patterns) of FIG. 3A satisfies the above-described conditions (1) and (2). In the measurement patterns of FIG. 3A, the length in which repetition occurs is twelve unit times, that is, twelve unit distances, and the return distance is length=12. The return distance, length=12, is the upper limit of the distance that can be measured. This is three times the distance in the example of FIG. 2 described above, and the distance that can be measured is extended. Furthermore, in the example of FIG. 3A, twelve unit times is one measurement period, and the light source section 11 emits the emission light 30 every measurement period.

The ranging method in the example in FIG. 3A will be schematically described. Similarly to the above, as depicted in the upper side of FIG. 3A, it is based on the premise that the reflection light 32 reaches the light receiving section 12 at timing delayed by the time ΔT with respect to the emission light 30. In this case, if time ΔT<time T_{P}, the light receiving section 12 measures the reflection light 32 in a part of each of the measurement periods by the enable signals EN₃ and EN₄.

It is based on the premise that the light receiving section 12 measures the reflection light 32 separately as the amount of light N₃ in the measurement period by the enable signal EN₃ and the amount of light N₄ in the measurement period by the enable signal EN₄. In this case, since the measurement periods of the enable signals EN₃ and EN₄ have overlapping periods, the amount of light N₄ measured in the measurement period by the enable signal EN₄ corresponds to the amount of light N₁+N₂ in the example of FIG. 2.

In addition, the amount of light in a measurement period that does not overlap the measurement period by the enable signal EN₃ or EN₄ as the measurement target is subtracted from each of the amounts of light N₃ and N₄ as the amount of light by the ambient light. As a result, noise due to ambient light can be canceled out. In the example of FIG. 3A, the amount of light N₁ measured in the measurement period by the enable signal EN₁ is set as the amount of light by the ambient light.

The distance D in this case is calculated by Equation (4).

$$D = \frac{1}{2} c {T}_{p} \frac{{N}_{3} - {N}_{1}}{{N}_{4} - {N}_{1}} \qquad ( 4 )$$

Note that, in Equation (4), the fractional expression part on the latter part switches for every unit time in one frame. For example, in the first unit time at the beginning (the left end side) in FIG. 3A, the fractional expression part is “(N₃−N₁)/(N₄−N₁)” as in the above expression (4), however in a next second unit time, the fractional expression part switches to “(N₄−N₁)/(N₃−N₁)”. Furthermore, in a subsequent third unit time, the fractional part switches to “(N₂−N₁)/(N₃−N₁)”.

Note that, in actual measurement, since the number of signals obtained in one time of light source emission is small, it is common to repeat the light source emission a plurality of times until a sufficient number of signals are obtained and to integrate the signals obtained by the plurality of times of light source emission to perform ranging. Incidentally, a period from emission of the emission light 30 from the light source section 11 to subsequent emission of the emission light 30 is referred to as a repetition period. In addition, a period required to perform one time of ranging is referred to as a frame period.

FIG. 3B is a diagram for describing a repetition period and a frame period. In this example, the modulation code by Hamiltonian encoding depicted in FIG. 3A will be described as an example.

As depicted in FIG. 3B, in the modulation code, the return distance is length=12, and a period corresponding to the return distance of length=12 is the repetition period. In addition, in the example of FIG. 3B, n repetition periods are required to perform one time of ranging, and the n repetition periods are set as one frame period. That is, one frame period is the measurement period for performing ranging using a certain modulation code.

Hereinafter, for the sake of explanation, it is based on the premise that one time of ranging is performed in one repetition period. In this case, the repetition period matches the frame period, and one repetition period is one measurement period. Incidentally, in the following description, a “frame period” may be simply abbreviated as a “frame.”

### 1-3. About Related Technology

### 1-3-1. Example of Light Receiving Element of Related Technology

Next, ranging of the indirect ToF according to related technology will be schematically described. In the related technology, a light receiving element including a plurality of gates for one photoelectric conversion section may be used from the viewpoint of area efficiency and the like. Such a light receiving element is referred to as a dual gate photodiode (PD). In addition, indirect ToF using the dual gate PD as a light receiving element will be referred to as gate iToF.

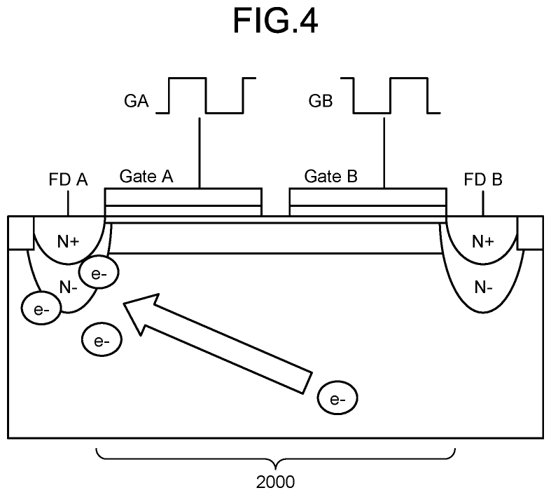

FIG. 4 is a cross-sectional view depicting an example of the structure of a dual gate PD according to related technology. Note that the dual gate PD depicted in FIG. 4 is configured such that light enters from the lower face of the drawing. In FIG. 4, in the dual gate PD, two gates Gate A and Gate B are included for one photoelectric conversion section 2000. The open or closed states of the gates Gate A and Gate B are exclusively controlled by gate signals GA and GB, respectively.

For example, in a case where the gate signal GA is in a high state and gate signal GB is in a low state, the gate Gate A is in an open state and the gate Gate B is in a closed state. In this case, electrons generated by light entering the photoelectric conversion section 2000 are transferred from the gate Gate A in the open state to a floating diffusion layer FD A adjacent to the Gate A. The electrons transferred to the floating diffusion layer FD A are converted into a voltage and read out from the floating diffusion layer FD A.

On the other hand, when the gate signal GB enters a high state and the gate signal GA enters a low state, the gate Gate B enters an open state, and the gate Gate A enters a closed state. In this case, electrons generated by light entering the photoelectric conversion section 2000 are transferred from the gate Gate B in the open state to a floating diffusion layer FD B adjacent to the Gate B. The electrons transferred to the floating diffusion layer FD B are converted into a voltage and read out from the floating diffusion layer FD B.

As described above, in the dual gate PD, the electrons generated by the photoelectric conversion section 2000 are distributed to the two taps of the gate Gate A and the Gate B.

### 1-3-2. Example of Measurement Method in which Hamiltonian Encoding is Applied to Related Technology

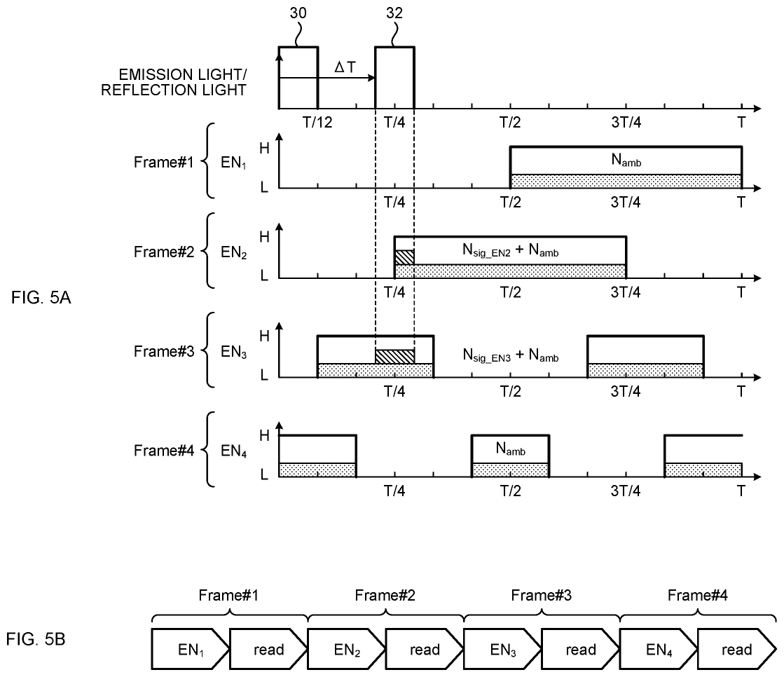

A case where the dual gate PD is applied to ranging process by the above-described Hamiltonian encoding will be considered. FIG. 5 is a schematic diagram depicting an example in which a dual gate PD is applied to the modulation code by Hamiltonian encoding. In FIG. 5, Chart (a) depicts an example of the emission light 30 from the light source section 11, the reflection light 32 which is the emission light 30 reflected by the measurement object 31, and the enable signals EN₁ to EN₄ based on the modulation code by Hamiltonian encoding. The measurement patterns by the enable signals EN₁ to EN₄ are the same as the measurement patterns by the enable signals EN₁ to EN₄ in FIG. 3A. Note that, in FIG. 3A, the length of the repetition period of each of the enable signals EN₁ to EN₄ is represented as a time T.

It is based on the premise that the reflection light 32 is received over a time T/4 in response to the emission light 30. In this case, an amount of light N_{sig_EN2} is measured on the basis of a part of the reflection light 32 during a measurement period by the enable signal EN₂. Presuming that the amount of ambient light is denoted as the amount of light N_{amb}, the amount of light N₂ measured in the measurement period is expressed as the amount of light N_{sig_EN2}+the amount of light N_{amb}. Meanwhile, an amount of light N_{sig_EN3} is measured on the basis of all of the reflection light 32 during a measurement period by the enable signal EN₃. Presuming that the amount of ambient light is denoted as the amount of light N_{amb}, the amount of light N₃ measured in the measurement period is expressed as the amount of light N_{sig_EN3}+the amount of light N_{amb}.

Incidentally, in Hamiltonian encoding, in a case where the origins of the enable signals EN₁ to EN₄ are aligned, overlapping portions occur in the measurement periods by the enable signals EN₁ to EN₄. In the dual gate PD described above, since the gate Gate A and the gate Gate B are exclusively controlled, measurement by the enable signals EN₁ to EN₄ cannot be executed in parallel. Therefore, it is necessary to perform measurement by the enable signals EN₁ to EN₄ separately in different frames.

In Chart (a) of FIG. 5, the measurement by the enable signals EN₁, EN₂, EN₃, and EN₄ is performed by the frames Frame #1, Frame #2, Frame #3, and Frame #4, respectively. That is, the measurement by the enable signals EN₁ to EN₄ is sequentially executed by the frames Frame #1 to Frame #4 as depicted in Chart (b) of FIG. 5.

As described above, in a case where the dual gate PD is used as the light receiving element, opening and closing of the plurality of gates are exclusively controlled, and thus it is necessary to acquire the plurality of modulation codes in different frames. In particular, in coding in which measurement periods overlap in measurement patterns having different phases, such as Hamiltonian encoding, the number of divisions of the frames Frame #1 to Frame #4 increases. Therefore, the amount of light that can be used is divided in the frames Frame #1 to Frame #4, which causes a signal loss. For example, in the frame Frame #1, since the measurement period starts from a seventh unit time, among output signals Voᵢᵥ output from pixel circuits 10, signals corresponding to light reception for first to sixth unit times are wasted.

In addition, as depicted in Chart (b), since a read time, read, of a measurement result occurs in each of the frames Frame #1 to Frame #4, it is difficult to improve the frame rate.

Furthermore, in the subtraction for canceling the ambient light with respect to the measurement of the reflection light 32 in the measurement periods by the enable signals EN₂ and EN₃ described above, the noise due to the ambient light that is uncorrelated is increased by the sum of squares.

As depicted in the example of Chart (a) of FIG. 5, in a case where the measurement of the reflection light 32 is performed in the measurement periods of the enable signals EN₂ and EN₃, the amount of light measured in a measurement period of the enable signal EN₁ or EN₄ is used as the amount of light N_{amb} of the ambient light. However, since the measurement by the frames Frame #1 to Frame #4 is sequentially performed, the noise due to the ambient light acquired in a measurement period by the enable signal EN₁ or EN₄ has no correlation with the noise due to the ambient light acquired in each of the measurement periods by the enable signals EN₂ and EN₃. Therefore, for example, in the subtractions in the numerator and the denominator in the above-described Equation (4), the noise due to the ambient light is not canceled but conversely increases.

In addition, in the dual gate PD, it is also conceivable to provide more gates for one photoelectric conversion section. However, in this case, it is difficult to increase the number of taps (the number of distributions) while the characteristics as a device are maintained.

### 2. First Embodiment of Present Disclosure

Next, a first embodiment of the present disclosure will be described. In the first embodiment of the present disclosure, a single photon avalanche diode is used as the light receiving element used for ranging by the indirect ToF method. Hereinafter, a single photon avalanche diode is referred to as an SPAD. The SPADs have a characteristic that, when a large negative voltage that generates avalanche multiplication is applied to a cathode, an electron generated in response to incidence of one photon causes avalanche multiplication to cause a large current to flow. By using this characteristic of the SPADs, incidence of one photon can be detected with high sensitivity.

In addition, by performing threshold value determination on the output of an SPAD, it is possible to acquire a pulse represented by binary numbers of a high state and a low state in response to incidence of one photon. That is, in a case where an SPAD is used as a light receiving element, output thereof can be regarded as a digital signal such as a value of “1” in response to incidence of a photon.

### 2-1. Configuration Example Applicable to First Embodiment

Next, a configuration example that can be applied to the first embodiment will be described.

### 2-1-1. About Configuration Example of Ranging Device

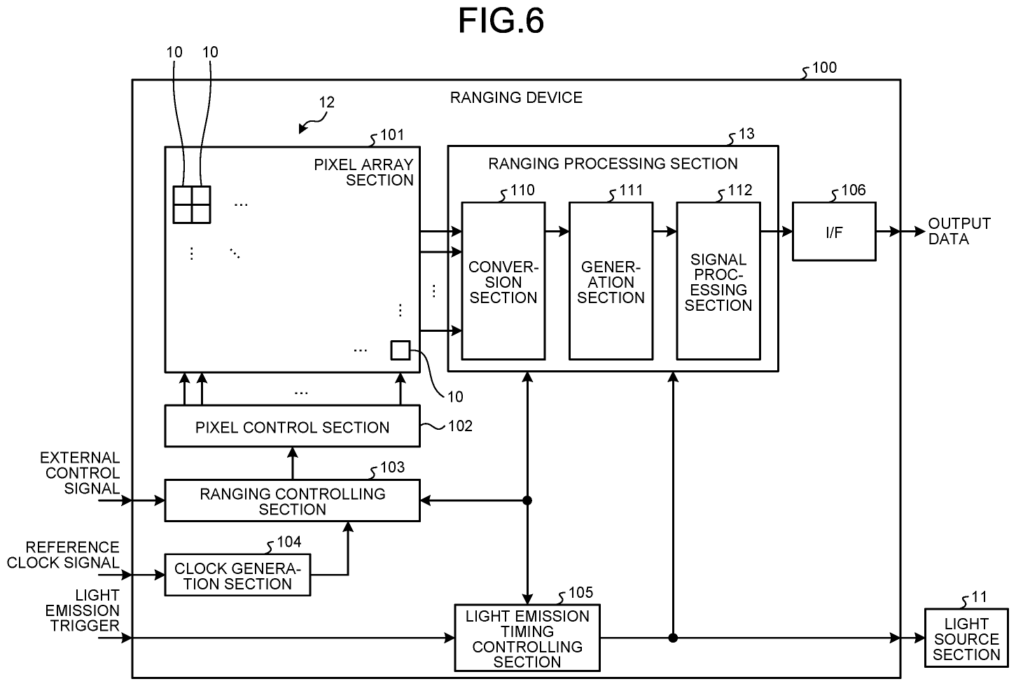

First, a configuration example of a ranging device using an SPAD as a light receiving element applicable to each embodiment of the present disclosure will be described with reference to FIG. 6. FIG. 6 is a block diagram depicting an example of a basic configuration of a ranging device 100 applicable to each embodiment in more detail. In FIG. 6, the ranging device 100 includes a pixel array section 101, the ranging processing section 13, a pixel control section 102, a ranging controlling section 103, a clock generation section 104, a light emission timing controlling section 105, and an interface (I/F) 106. The pixel array section 101, the ranging processing section 13, the pixel control section 102, the ranging controlling section 103, the clock generation section 104, the light emission timing controlling section 105, and the interface 106 are arranged on one semiconductor chip, for example.

In FIG. 6, the ranging controlling section 103 controls the overall operation of the ranging device 100 in accordance with, for example, a program incorporated therein in advance. For example, the ranging controlling section 103 generates the enable signals EN₁, EN₂, EN₃, . . . , and EN_{N}, and supplies the enable signals EN₁, EN₂, EN₃, . . . , and EN_{N} to the pixel control section 102 or the ranging processing section 13. Furthermore, the ranging controlling section 103 can also execute control in response to an external control signal supplied from the outside (for example, the total control section 14).

The clock generation section 104 generates one or more clock signals used in the ranging device 100 on the basis of a reference clock signal supplied from the outside (for example, the total control section 14). The light emission timing controlling section 105 generates a light emission control signal indicating light emission timing and light emission duration (unit time T_{P}) in accordance with a light emission trigger signal supplied from the outside (for example, the total control section 14). The light emission control signal is supplied to the light source section 11 and also to the ranging processing section 13.

The pixel array section 101 includes a plurality of pixel circuits 10, 10, . . . which is arranged in a matrix-shaped array and each including a light receiving element. The operation of each of the pixel circuits 10 is controlled by the pixel control section 102 following an instruction of the ranging controlling section 103. For example, the pixel control section 102 can control reading of pixel signals from the pixel circuits 10 for each block containing (p×q) pixel circuits 10 consisting of p pixel circuits 10 in a row direction and q pixel circuits 10 in a column direction. Furthermore, the pixel control section 102 can read the pixel signals from the pixel circuits 10 by scanning the pixel circuits 10 in the row direction and further scanning in the column direction block by block. Without being limited thereto, and the pixel control section 102 can control each of the pixel circuits 10 independently.

Furthermore, the pixel control section 102 can set a predetermined region of the pixel array section 101 as a target region and set pixel circuits 10 included in the target region as target pixel circuits 10 from which pixel signals are read. Furthermore, the pixel control section 102 can scan a plurality of rows (a plurality of lines) collectively, further scan the rows in the column direction, and read pixel signal from the pixel circuits 10.

The pixel signals read from the pixel circuits 10 are supplied to the ranging processing section 13. The ranging processing section 13 includes a conversion section 110, a generation section 111, and a signal processing section 112.

The pixel signals read from the pixel circuits 10 and output from the pixel array section 101 are supplied to the conversion section 110. Note that the pixel signals are asynchronously read from the pixel circuits 10 included in the target region and supplied to the conversion section 110. That is, the pixel signals are read and output from the light receiving elements depending on the timing at which light is received in each of the pixel circuits 10 included in the target region.

The conversion section 110 converts the pixel signals supplied from the pixel array section 101 into digital information. That is, a pixel signal supplied from the pixel array section 101 is output corresponding to the timing at which light is received by a light receiving element included in a pixel circuit 10 to which the pixel signal corresponds to. The conversion section 110 converts the pixel signal supplied thereto into time information indicating the timing.

The generation section 111 generates a histogram on the basis of the time information obtained by converting the pixel signals by the conversion section 110. Note that the generation section 111 includes a counter and classifies the time information on the basis of classes (bin(s)) corresponding to the unit time T_{P} set by a setting section 113, counts the time information by the counter for each bin, and generates the histogram.

The signal processing section 112 performs predetermined arithmetic processing on the basis of data of the histogram generated by the generation section 111 and calculates, for example, distance information. The signal processing section 112 obtains the amount of light N received in unit time T_{P} on the basis of, for example, the data of the histogram generated by the generation section 111. The signal processing section 112 can obtain the distance D on the basis of the amount of light N.

Ranging data indicating the distance D obtained by the signal processing section 112 is supplied to the interface 106. The interface 106 outputs the ranging data supplied from the signal processing section 112 to the outside as output data. As the interface 106, for example, a mobile industry processor interface (MIPI) can be applied.

Note that, in the above description, the ranging data indicating the distance D obtained by the signal processing section 112 is output to the outside via the interface 106, however, it is not limited to this example. That is, histogram data that is the data of the histogram generated by the generation section 111 may be output from the interface 106 to the outside. The histogram data output from the interface 106 is supplied to, for example, an external information processing device and processed as required.

### 2-1-2. About Light Receiving Element

### About Circuit Example and Operation Example

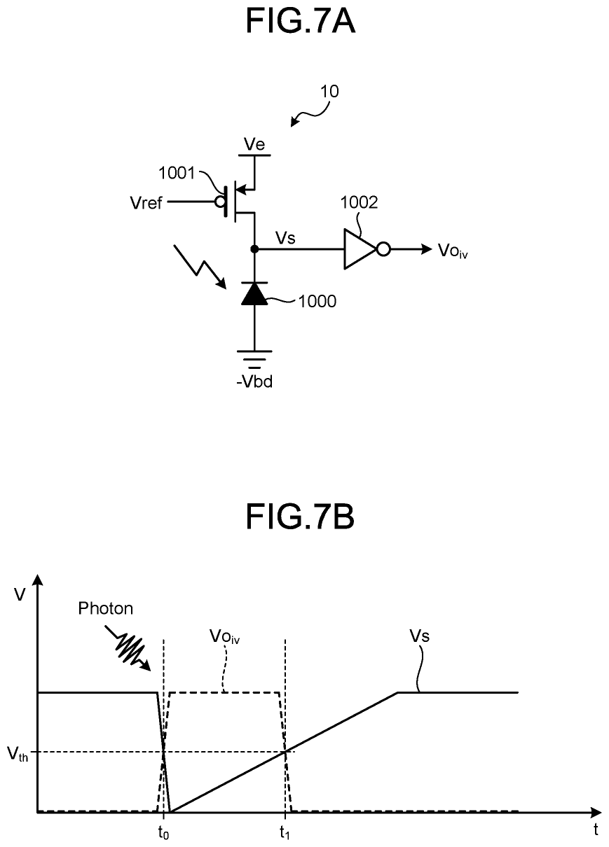

Next, an SPAD as a light receiving element applicable to each embodiment of the present disclosure will be schematically described. FIG. 7A is a diagram depicting a basic configuration example of a pixel circuit 10 applicable to each embodiment. Furthermore, FIG. 7B is a schematic graph depicting an example of a signal in a pixel circuit 10 applicable to each embodiment.

In FIG. 7A, the pixel circuit 10 includes a light receiving element 1000, a transistor 1001 that is a P-channel MOS transistor, and an inverter 1002. Note that an SPAD is applied as the light receiving element 1000.

The light receiving element 1000 converts incident light into an electric signal by photoelectric conversion and outputs the electric signal. In each embodiment, a light receiving element 1000 converts incident photons (photons) into electric signals by photoelectric conversion and outputs pulses corresponding to the incidence of the photons. The SPAD used as the light receiving element 1000 has a characteristic that, when a large negative voltage that generates avalanche multiplication is applied to a cathode, an electron generated in response to incidence of one photon causes avalanche multiplication to cause a large current to flow. By using this characteristic of the SPAD, incidence of one photon can be detected with high sensitivity.

In FIG. 7A, in the light receiving element 1000 which is the SPAD, a cathode is connected to a drain of the transistor 1001, and an anode is connected to a voltage source of a negative voltage (−Vbd) corresponding to a breakdown voltage of the light receiving element 1000. A source of the transistor 1001 is connected to a voltage Ve. A reference voltage Vref is input to a gate of the transistor 1001. The transistor 1001 is a current source that outputs a current corresponding to the voltage Ve and the reference voltage Vref from the drain. With such a configuration, a reverse bias is applied to the light receiving element 1000. Incidentally, a photoelectric current flows in a direction from the cathode toward the anode of the light receiving element 1000.

More specifically, in the light receiving element 1000, when a photon is incident in a state where a voltage (−Vbd) is applied to the anode and charged by a potential (−Vdb), avalanche multiplication is started, a current flows from the cathode toward the anode, and accordingly, a voltage drop occurs in the light receiving element 1000. When a voltage Vs between the anode and the cathode of the light receiving element 1000 drops to the voltage (−Vbd) due to the voltage drop, the avalanche multiplication is stopped (quenching operation). Thereafter, the light receiving element 1000 is charged by a current (recharge current) from the transistor 1001 as a current source, and the state of the light receiving element 1000 returns to the state before the incidence of the photon (recharge operation).

Here, the quenching operation and the recharge operation are passive operations performed without external control.

The voltage Vs drawn from a connection point between the drain of the transistor 1001 and the cathode of the light receiving element 1000 is input to the inverter 1002. The inverter 1002 performs, for example, threshold value determination on the input voltage Vs and inverts the output signal Voᵢᵥ every time the voltage Vs exceeds a threshold voltage Vth in the positive direction or the negative direction.

More specifically, referring to FIG. 7B, the inverter 1002 inverts the output signal Voᵢᵥ at a time point t₀ when the voltage Vs exceeds the threshold voltage Vth in the voltage drop due to the avalanche multiplication corresponding to the incidence of a photon on the light receiving element 1000. Next, the light receiving element 1000 is charged by the recharge operation, and the voltage Vs rises. The inverter 1002 inverts the output signal Voᵢᵥ again at a time point t₁ when the rising voltage Vs exceeds the threshold voltage Vth. The width in the time direction between the time point t₀ and the time point t₁ is an output pulse corresponding to the incidence of a photon on the light receiving element 1000. The inverter 1002 shapes and outputs the output pulse.

That is, the inverter 1002 has a function of a detection section that detects a voltage based on a current flowing through the light receiving element 1000 by avalanche multiplication, inverts the output signal Voᵢᵥ in a case where a voltage value of the detected voltage exceeds a threshold value, and shapes the inverted output signal Voᵢᵥ into a pulse signal and outputs the pulse signal.

The shaped output pulse corresponds to the pixel signal asynchronously output from the pixel array section 101 described with reference to FIG. 6. In FIG. 6, the conversion section 110 converts the output pulse into time information indicating the timing at which the output pulse has been supplied and passes the time information to the generation section 111. The generation section 111 generates a histogram on the basis of the time information.

### About Structure Example

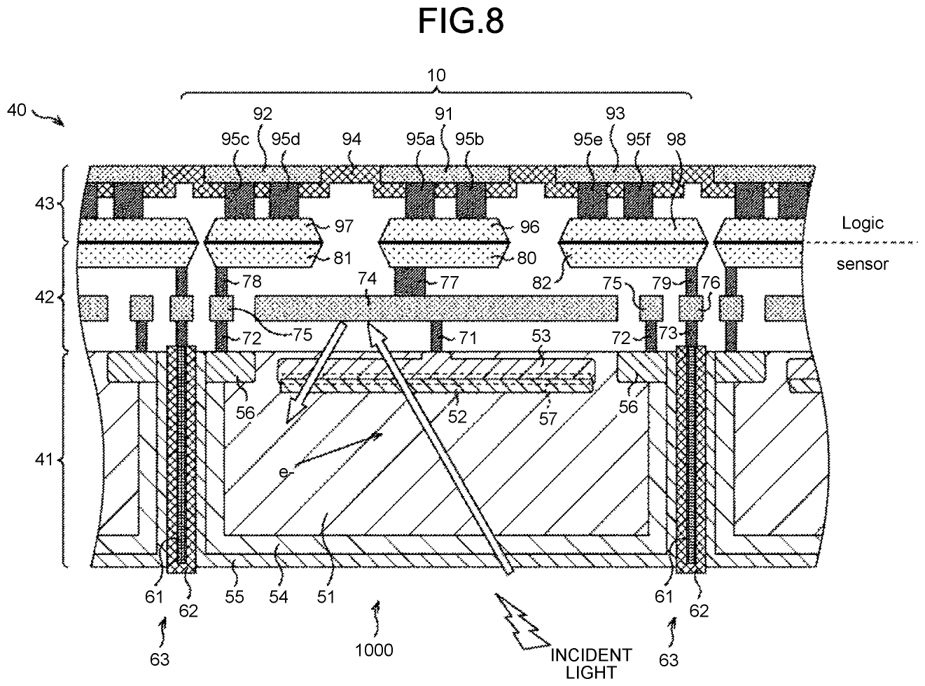

FIG. 8 is a diagram depicting an exemplary structure of a part of a pixel circuit 10 formed on a sensor chip 40 applicable to each embodiment. In FIG. 8, a cross-sectional structure example of a part of the pixel circuit 10 is depicted.

As depicted in FIG. 8, the sensor chip 40 has a laminated structure in which a sensor substrate 41, a sensor-side wiring layer 42, and a logic-side wiring layer 43 are laminated, and a logic circuit board (not depicted) is laminated on the logic-side wiring layer 43. For example, the transistor 1001, the inverter 1002, and others in FIG. 7A are formed in the logic circuit board. For example, the sensor chip 40 can be manufactured by a manufacturing method in which the sensor-side wiring layer 42 is formed for the sensor substrate 41, the logic-side wiring layer 43 is formed for the logic circuit board, and then the sensor-side wiring layer 42 and the logic-side wiring layer 43 are bonded together at bonding surfaces (surfaces indicated by a broken line in FIG. 8).

The sensor substrate 41 is, for example, a semiconductor substrate obtained by thinly slicing single crystal silicon, and a p-type or n-type impurity concentration is controlled, and the light receiving element 1000 which is an SPAD is formed for each pixel circuit 10. In addition, in FIG. 8, a face of the sensor substrate 41 facing downward is the light receiving face that receives light, and the sensor-side wiring layer 42 is laminated on a surface opposite to the light receiving face.

In the sensor-side wiring layer 42 and the logic-side wiring layer 43, wiring for supplying a voltage to be applied to the light receiving element 1000, wiring for extracting electrons generated in the light receiving element 1000 from the sensor substrate 41, and others are formed.

A light receiving element 1000 includes an N-well 51, a P-type diffusion layer 52, an N-type diffusion layer 53, a hole accumulation layer 54, a pinning layer 55, and high-concentration P-type diffusion layers 56 formed in the sensor substrate 41. Then, in the light receiving element 1000, an avalanche multiplication region 57 is formed by a depletion layer formed in a region where the P-type diffusion layer 52 and the N-type diffusion layer 53 are connected.

The N-well 51 is formed by controlling the impurity concentration of the sensor substrate 41 to be that of the n-type and forms an electric field that transfers electrons generated by photoelectric conversion in the light receiving element 1000 to the avalanche multiplication region 57. Note that, instead of the N-well 51, the impurity concentration of the sensor substrate 41 may be controlled to be that of the p-type to form a P-well.

The P-type diffusion layer 52 is a dense P-type diffusion layer (P+) formed in the vicinity of a top face of the sensor substrate 41 and on the back face side (downward in FIG. 8) with respect to the N-type diffusion layer 53 and is formed over substantially the entire surface of the light receiving element 1000.

The N-type diffusion layer 53 is a dense N-type diffusion layer (N+) formed in the vicinity of the top face of the sensor substrate 41 and on a top face side (upper side in FIG. 8) with respect to the P-type diffusion layer 52 and is formed over substantially the entire surface of the light receiving element 1000. In addition, the N-type diffusion layer 53 has a protruding shape in which a part thereof is formed up to the top face of the sensor substrate 41 in order to be in contact with a contact electrode 71 for supplying a negative voltage for forming the avalanche multiplication region 57.

The hole accumulation layer 54 is a P-type diffusion layer (P) formed in such a manner as to surround side faces and a bottom face of the N-well 51 and accumulates holes. The hole accumulation layer 54 is electrically connected with the anode of the light receiving element 1000, thereby enabling bias adjustment. As a result, the hole concentration of the hole accumulation layer 54 is enhanced, and pinning including that in the pinning layer 55 is strengthened, which can suppress, for example, generation of a dark current.

The pinning layer 55 is a dense P-type diffusion layer (P+) formed on surfaces external to the hole accumulation layer 54 (the back face of the sensor substrate 41 and side faces in contact with insulating films 62) and, for example, suppresses generation of a dark current similarly to the hole accumulation layer 54.

A high-concentration P-type diffusion layer 56 is a dense P-type diffusion layer (P++) formed in such a manner as to surround the outer circumference of the N-well 51 in the vicinity of the top face of the sensor substrate 41 and is used for connection with a contact electrode 72 for electrically connecting the hole accumulation layer 54 to the anode of the light receiving element 1000.

The avalanche multiplication region 57 is a high electric field region formed at the boundary surface between the P-type diffusion layer 52 and the N-type diffusion layer 53 by a large negative voltage applied to the N-type diffusion layer 53 and multiplies an electron (e−) generated by one photon incident on the light receiving element 1000.

Furthermore, in the sensor chip 40, each light receiving element 1000 is insulated and separated by inter-pixel separators 63 having a double structure including a metal film 61 and an insulating film 62 formed between adjacent light receiving elements 1000. For example, an inter-pixel separator 63 is formed in such a manner as to penetrate from the back face to the top face of the sensor substrate 41.

The metal film 61 is formed of a metal (such as tungsten) that reflects light, and the insulating film 62 has an insulating property such as SiO₂. For example, the inter-pixel separator 63 is formed with the metal film 61 embedded in the sensor substrate 41 in such a manner that the surfaces of the metal film 61 are covered with the insulating film 62, and the inter-pixel separator 63 electrically and optically separates adjacent light receiving elements 1000.

In the sensor-side wiring layer 42, contact electrodes 71 to 73, metal wiring 74 to 76, contact electrodes 77 to 79, and metal pads 80 to 82 are formed.

The contact electrode 71 connects the N-type diffusion layer 53 and the metal wiring 74, the contact electrodes 72 connect the high-concentration P-type diffusion layers 56 and the metal wiring 75, and a contact electrode 73 connects a metal film 61 and metal wiring 76.

For example, the metal wiring 74 is formed to be wider than the avalanche multiplication region 57 in such a manner as to cover at least the avalanche multiplication region 57. The metal wiring 74 further reflects the light transmitted through the light receiving element 1000 to the light receiving element 1000 as indicated by white hollow arrows in FIG. 8.

The metal wiring 75 is formed so as to overlap with the high-concentration P-type diffusion layer 56 in such a manner as to surround the outer circumference of the metal wiring 74, for example. The metal wiring 76 is formed in such a manner as to be connected to metal films 61 at four corners of the pixel circuit 10, for example.

The contact electrode 77 connects the metal wiring 74 and the metal pad 80, the contact electrode 78 connects the metal wiring 75 and the metal pad 81, and the contact electrode 79 connects the metal wiring 76 and the metal pad 82.

The metal pads 80 to 82 are used to be electrically and mechanically bonded to the metal pads 96 to 98 formed in the logic-side wiring layer 43, respectively, to each other by metal (Cu) forming the metal pads.

In the logic-side wiring layer 43, electrode pads 91 to 93, an insulating layer 94, contact electrodes 95a to 95f, and the metal pads 96 to 97 are formed.

Each of the electrode pads 91 to 93 is used for connection with a logic circuit board (not depicted), and the insulating layer 94 insulates the electrode pads 91 to 93 from each other.

The contact electrodes 95a and 95b connect the electrode pad 91 and the metal pad 96, the contact electrodes 95c and 95d connect the electrode pad 92 and the metal pad 97, and the contact electrodes 95e and 95f connect the electrode pad 93 and the metal pad 98.

The metal pad 96 is bonded to the metal pad 80, the metal pad 97 is bonded to the metal pad 81, and the metal pad 98 is bonded to the metal pad 82.

With such a wiring structure, for example, the electrode pad 91 is connected to the N-type diffusion layer 53 via the contact electrodes 95a and 95b, the metal pad 96, the metal pad 80, the contact electrode 77, the metal wiring 74, and the contact electrode 71. Therefore, in the pixel circuit 10, a large negative voltage applied to the N-type diffusion layer 53 can be supplied from the logic circuit board to the electrode pad 91.

In addition, the electrode pad 92 is connected to the high-concentration P-type diffusion layer 56 via the contact electrodes 95c and 95d, the metal pad 97, the metal pad 81, the contact electrode 78, the metal wiring 75, and the contact electrode 72. Therefore, in the pixel circuit 10, with the anode of the light receiving element 1000 electrically connected with the hole accumulation layer 54 being connected to the electrode pad 92, it is possible to adjust the bias with respect to the hole accumulation layer 54 via the electrode pad 92.

Moreover, the electrode pad 93 is connected to the metal film 61 via the contact electrodes 95e and 95f, the metal pad 98, the metal pad 82, the contact electrode 79, the metal wiring 76, and the contact electrode 73. Therefore, in the pixel circuit 10, a bias voltage supplied from the logic circuit board to the electrode pad 93 can be applied to the metal film 61.

Furthermore, in the pixel circuit 10, as described above, the metal wiring 74 is formed to be wider than the avalanche multiplication region 57 in such a manner as to cover at least the avalanche multiplication region 57, and the metal film 61 is formed in such a manner as to penetrate the sensor substrate 41. That is, the pixel circuit 10 is formed to have a reflection structure in which the metal wiring 74 and metal films 61 surround the entire portion other than a light incident face of the light receiving element 1000. As a result, the pixel circuit 10 can prevent occurrence of optical crosstalk and improve the sensitivity of the light receiving element 1000 by the effect of reflecting light by the metal wiring 74 and the metal films 61.

In addition, the pixel circuit 10 can enable bias adjustment by a connection configuration in which the side faces and the bottom face of the N-well 51 are surrounded by the hole accumulation layer 54, and the hole accumulation layer 54 is electrically connected with the anode of the light receiving element 1000. Furthermore, in the pixel circuit 10, an electric field that assists carriers in the avalanche multiplication region 57 can be formed by a bias voltage applied to the metal films 61 of the inter-pixel separators 63.

In the pixel circuit 10 configured as described above, occurrence of crosstalk is prevented, and the sensitivity of the light receiving element 1000 is improved, and as a result, the characteristics can be improved.

### 2-2. Configuration Example According to First Embodiment

Next, a configuration example according to the first embodiment will be described. As described above, by using the SPAD as the light receiving element 1000 of each of the pixel circuits 10 of the pixel array section 101, pixel signals output from each of the pixel circuits 10 can be treated as digital signals. Therefore, the pixel signals output from the pixel circuit 10 can be distributed to a plurality of paths, and two or more of the plurality of paths can be turned on at the same time.

### 2-2-1. Example of Light Receiving Circuit

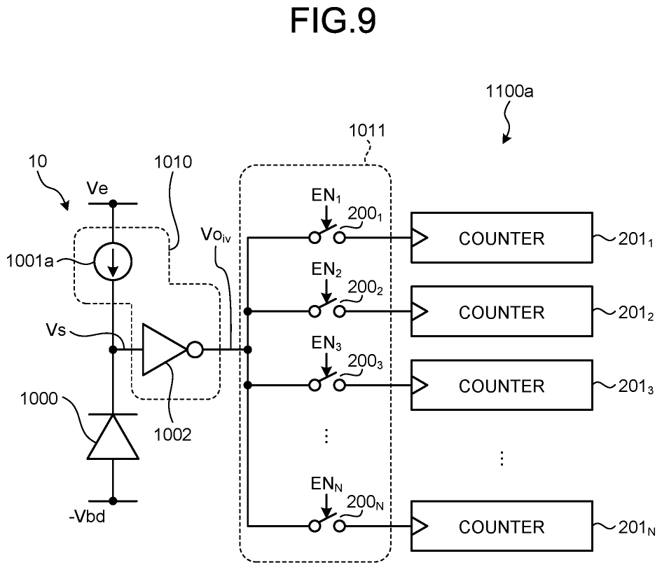

FIG. 9 is a diagram depicting an example of a light receiving circuit according to the first embodiment. In FIG. 9, a light receiving circuit 1100a is configured as a light receiving device including a pixel circuit 10, a distribution circuit 1101 that distributes the output of the pixel circuit 10 to N paths, and a plurality of counters 201₁, 201₂, 201₃, . . . , and 201_{N} depending on the number of paths distributed by the distribution circuit 1101. Furthermore, in FIG. 9, a current source 1001a of the pixel circuit 10 corresponds to the transistor 1001 in FIG. 7A, and the current source 1001a and an inverter 1002 are included in a front end 1010 of the light receiving element 1000.

An output signal Voᵢᵥ output from the pixel circuit 10 is input to the distribution circuit 1011. The distribution circuit 1011 selects target counters for counting the output signal Voᵢᵥ from the plurality of counters 201₁ to 201_{N}.

Specifically, the distribution circuit 1011 distributes the output signal Voᵢᵥ input thereto to N paths and supplies the output signal Voᵢᵥ to the counters 201₁, 201₂, 201₃, . . . , and 201_{N} via switch circuits 200₁, 200₂, 200₃, . . . , and 200_{N}, respectively. An on (closed) state and an off (open) state of each of the switch circuits 200₁, 200₂, 200₃, . . . , and 200_{N} are controlled by enable signals EN₁, EN₂, EN₃, . . . , and EN_{N}, respectively.

Note that, in FIG. 9, the distribution circuit 1011 and the counters 201₁ to 201_{N} are included in the generation section 111 in FIG. 6, for example. Each output signal Voᵢᵥ output from each of the pixel circuits 10 is converted into time information in a conversion section 110 (not depicted) and is counted in a bin corresponding to the time information of a histogram in the counters 201₁ to 201_{N}.

### 2-2-2. Example of Measurement Method

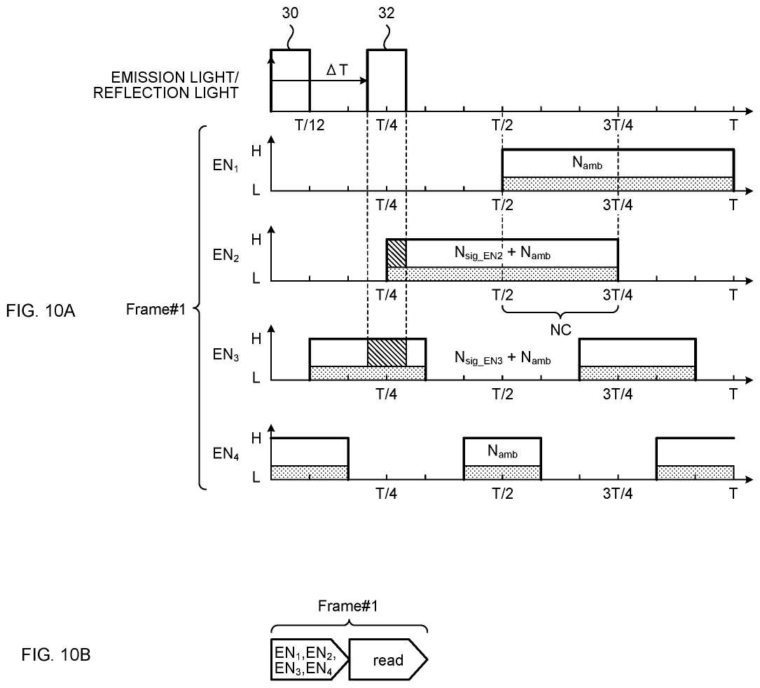

FIG. 10 is a schematic diagram for describing an example of a measurement method according to the first embodiment. In FIG. 10, the meanings of Chart (a) and Chart (b) are similar to those of Chart (a) and Chart (b) of FIG. 5 described above, and thus the description thereof is omitted here. Furthermore, in this example, the modulation code based on Hamiltonian encoding described with reference to FIG. 3A is applied as the modulation code for designating a measurement period in which measurement based on the output of the light receiving section 12 is performed.

Incidentally, it is based on the premise that the distribution circuit 1011 depicted in FIG. 9 distributes the output signal Voᵢᵥ output from the pixel circuit 10 to four paths. In Chart (a) of FIG. 10, measurement patterns of the enable signals EN₁ to EN₄ corresponding to the respective four paths are the same as the measurement patterns of the enable signals EN₁ to EN₄ of FIG. 3A and Chart (a) of FIG. 5. In addition, similarly to FIG. 3A and Chart (a) of FIG. 5, the length of repetition is twelve unit times, and these twelve unit times are the length of the repetition period (denoted as time T).

Similarly to Chart (a) of FIG. 5, it is based on the premise that the reflection light 32 is received in response to the emission light 30 over the time T/4 after the time ΔT from emission time of the emission light 30. The output signal Voᵢᵥ output from the pixel circuit 10 is distributed to four paths by the distribution circuit 1011 and is input to one or more counters (target counters) to be measured among the counters 201₁ to 201₄ in accordance with the enable signals EN₁ to EN₄.

Specifically, the enable signal EN₃ is in the high state at the time ΔT, and the counter 201₃ is set as the target counter by the high state of the enable signal EN₃. The output signal Voᵢᵥ is input to the counter 201₃, which is a target counter, in accordance with the high state of the enable signal EN₃ at the time ΔT.

Note that the modulation code, to which the Hamiltonian encoding is applied, depicted in FIG. 10 satisfies the above-described conditions (1) and (2). Therefore, the distribution circuit 1011 selects at least one counter among the plurality of counters 201₁ to 201₄ as a target counter to be counted on the basis of the output signal Voᵢᵥ in accordance with the enable signals EN₁ to EN₄. In addition, this modulation code includes a state in which two counters among the plurality of counters 201₁ to 201₄ are simultaneously selected in the same unit time.

Next, after the time T/4 of the emission time of the emission light 30 elapses, the enable signal EN₂ enters a high state, and the counter 201₂ is further set as a target counter due to the high state of the enable signal EN₂. At time T/4, the output signal Voᵢᵥ is further input to the counter 201₂ which is the target counter due to the high state of the enable signal EN₂.

In this case, during the measurement period by the enable signal EN₂, a part of the reflection light 32 is measured as the amount of light N_{sig_EN2}, and the amount of light N₂ received during the measurement period is expressed as the amount of light N_{sig_EN2}+the amount of light N_{amb}. The amount of light N_{sig_EN2}+the amount of light N_{amb} is the number of photons counted by the counter 201₂.

Meanwhile, all of the reflection light 32 is received as the amount of light N_{sig_EN2} during the measurement period by the enable signal EN₃. The amount of light N₃ measured in the measurement period is expressed as the amount of light N_{sig_EN2}+the amount of light N_{amb}. The amount of light N_{sig_EN3}+the amount of light N_{amb} is the number of photons counted by the counter 201₃.

Incidentally, as described above, a pixel signal based on output of the light receiving element 1000, which is an SPAD, can be treated as a digital signal. Therefore, measurement by the enable signals EN₁ to EN₄ can be executed in parallel. That is, by using an SPAD as the light receiving element 1000, it becomes possible to digitally distribute the output signal Voᵢᵥ of the pixel circuit 10 and to distribute, within one frame, modulation patterns in which a plurality of pieces of measurement is executed at the same time.

More specifically, in the first embodiment, the output signal Voᵢᵥ output from the pixel circuit 10 is distributed to four paths by the distribution circuit 1011 and is input to the counters 201₁ to 201₄ via the switch circuits 200₁ to 200₄, respectively. If all the switch circuits 200₁ to 200₄ are in the on state, each of the counters 201₁ to 201₄ measures the same number of photons.

The on state and the off state of the switch circuits 200₁ to 200₄ are controlled in parallel temporally within a period of one frame by the enable signals EN₁ to EN₄ depicted in Chart (a) of FIG. 10. The counters 201₁ to 201₄ each measure the common output signal Voᵢᵥ in a measurement period controlled by the respective enable signals EN₁ to EN₄.

Therefore, in the configuration according to the first embodiment, as depicted in Chart (b) of FIG. 10, the pieces of measurement by the enable signals EN₁ to EN₄ can be completed within one frame including reading of the measurement results.

Note that the above-described Equation (4) can be applied for calculation of the distance D based on the measurement results. Similarly to the above, the distance D is calculated by switching the content of the fractional expression part of Equation (4) every unit time.

In addition, in the configuration according to the first embodiment, since the pieces of measurement using the plurality of measurement patterns is executed in parallel, the loss of the output signal Vo output from the pixel circuit 10 can be suppressed. For example, in a frame Frame #1, since the measurement period starts from a seventh unit time, the output in first to sixth unit times out of the output signal Voᵢᵥ output from the pixel circuit 10 is not used. Meanwhile, in frames Frames #2 to #4, the output signal Voᵢᵥ in the first to sixth unit times is used. Therefore, when the frames Frames #1 to #4 are comprehensively viewed, it can be seen that the output signal Voᵢᵥ in one frame is effectively used.

Furthermore, since the counters 201₁ to 201₄ measure the common output signal Voᵢᵥ, pieces of measurement information generated at the same time in the plurality of measurement patterns to which the output signal Voᵢᵥ has been distributed have a correlation. Therefore, in a period in which measurement periods overlap in a plurality of measurement patterns, noise such as ambient light can be completely canceled.

As an example, in the example of Chart (a) of FIG. 10, a case will be considered in which the amount of light N_{amb} by the ambient light is removed from the amount of light N_{sig_EN2} in a measurement period by the enable signal EN₂. In this case, completely the same measurement results can be obtained in the measurement period indicated by a period NC and, for example, a measurement period by the enable signal EN₁. Therefore, by subtracting the measurement result in the overlapping period NC in the measurement period by the enable signal EN₁ from the measurement result in the measurement period by the enable signal EN₂, the ambient light component in the period NC in the measurement period by the enable signal EN₂ is completely removed, and the removal of the ambient light can be efficiently executed.

### 2-2-3. Exemplary Effects

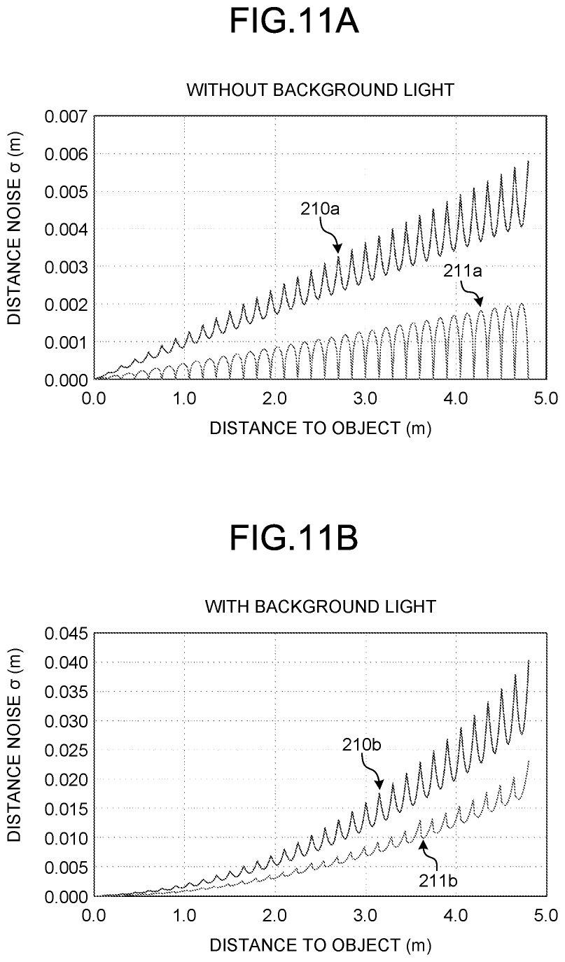

FIGS. 11A and 11B are graphs for describing an effect of the ranging method according to the first embodiment. In FIGS. 11A and 11B, the horizontal axis represents the distance D [m] to an object for ranging (measurement object 31), and the vertical axis represents the distance noise σ [m]. Note that the distance noise σ is a value indicating fluctuation of a ranging result and indicates that more accurate ranging is possible as the value is smaller. Furthermore, FIG. 11A depicts an example of a case where there is no background light (ambient light), and FIG. 11B depicts an example of a case where there is background light. In addition, FIGS. 11A and 11B each depict examples of a case where Hamiltonian encoding is used as the modulation code and the total laser light amount (exposure time), the photon reaction rate in the pixel circuit 10, and optical conditions are matched.

In FIGS. 11A and 11B, characteristic lines 210a and 210b each depict examples of distance noise σ according to the related technology, and characteristic lines 211a and 211b each depict examples of distance noise σ by ranging according to the first embodiment. In both of FIGS. 11A and 11B, it can be seen that the distance noise σ according to the first embodiment is smaller than the distance noise σ according to the related technology and that the distance noise σ is improved. This is because the loss of a signal is eliminated by using the SPAD as the light receiving element 1000 and simultaneously distributing the output signal Voᵢᵥ to multiple phases.

In addition, in this example, a comparison result is depicted for a case where a modulation code based on Hamiltonian encoding of an order of “4” (four distributions) is used, however, the improved amount can be further increased by using a modulation code based on Hamiltonian encoding of a larger order (described later).

### 2-2-4. Extension Example

Next, as an extension example of the first embodiment, a modulation code based on the Hamiltonian decoding having a larger order will be described. In Hamiltonian encoding, the return distance length can be calculated by Equations (5) and (6). Note that Equation (5) shows a case where the order k is an odd number, and Equation (6) shows a case where the order k is an even number.

length=2^{k}−2(k is an odd number) (5)

length=2^{k}−4(k is an even number) (6)

According to the Equations (5) and (6), the return distance length in the case of k=4 to 8 is as follows. In a case where Hamiltonian encoding is applied to the modulation code in this manner, the return distance length is doubled or more by increasing the number of distributions by one, and the distance that can be measured can be extended.
k=4:length=12
k=5:length=30
k=6:length=60
k=7:length=126
k=8:length=252

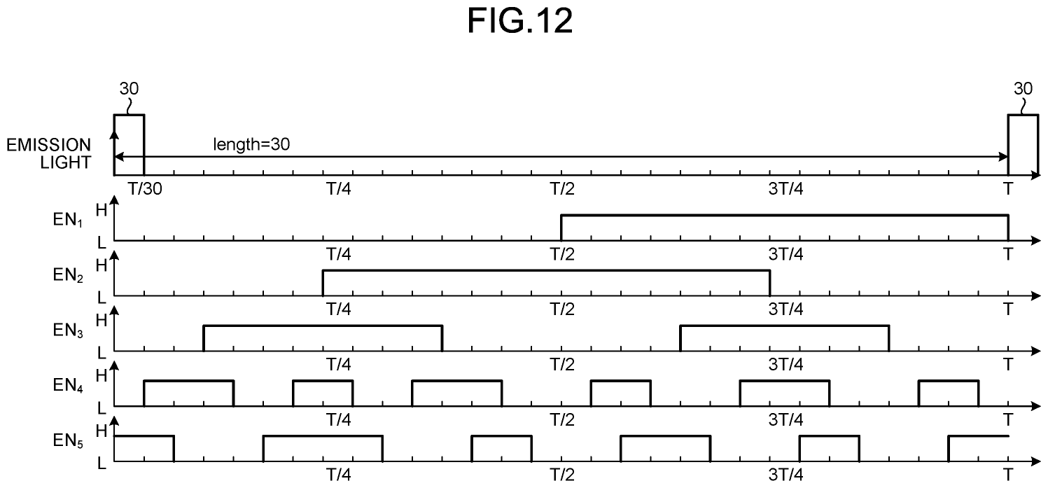

FIG. 12 is a diagram depicting an example of a modulation code by Hamiltonian encoding in the case of the order k=5, which is applicable to the first embodiment. The modulation code includes five measurement patterns corresponding to the order k=5, and the five measurement patterns are implemented by five enable signals EN₁, EN₂, EN₃, EN₄, and EN₅.

In the example of FIG. 12, the enable signal EN₁ is set to a low state in a period of twelve unit times from the origin, a high state in a period of the next twelve unit times, and the enable signal EN₂ is set to a low state in a period of the first seven unit times, a high state in a period of the next fifteen unit times, and a low state in a period of the subsequent eight unit times. The enable signal EN₃ is, in a time series, set to a low state for three unit times, a high state for eight unit times, a low state for eight unit times, a high state for seven unit times, and a low state for four unit times. In addition, the enable signal EN₄ is a combination of a low state for one to three unit times and a high state for two and three unit times. Furthermore, the enable signal EN₅ is a combination of a low state for three unit times and a high state for two to four unit times.

The measurement patterns in FIG. 12 satisfy the above-described conditions (1) and (2). In addition, in the measurement patterns of FIG. 12, since the order k=5, the return distance length=30, and the return distance length=30 is the upper limit of the distance that can be measured.

As described above, in a case where Hamiltonian encoding is used as the modulation code, the larger the order k is, the farther the ranging can be performed. The order k is preferably selected depending on the amount light of the light source section 11, a ranging target, or others.

### 2-3. First Modification of First Embodiment

Next, a first modification of the first embodiment will be described. The first modification of the first embodiment is an example in which binning is performed to read a pixel signal regarding that a plurality of pixel circuits 10 is one pixel.

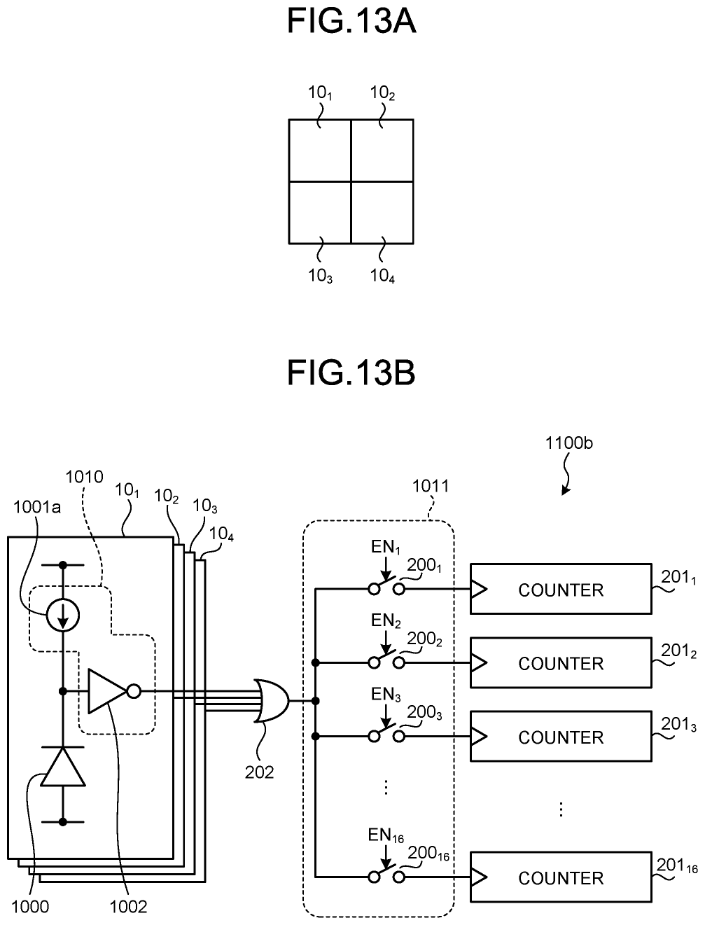

FIGS. 13A and 13B are diagrams for describing the binning according to the first modification of the first embodiment. For example, as depicted in FIG. 13A, four pixel circuits 10₁, 10₂, 10₃, and 10₄ arranged in a lattice pattern are binned, and these pixel circuits 10₁ to 10₄ are regarded as one pixel.

Note that the number of pixel circuits 10 to be binned is not limited to four. Two or three pixel circuits 10 may be binned, or five or more pixel circuits 10 may be binned.

FIG. 13B is a diagram depicting an example of a light receiving circuit according to the first modification of the first embodiment. In FIG. 13B, in a light receiving circuit 1100b, output signals Voᵢᵥ output from four pixel circuits 10₁ to 10₄ are integrated by a logical sum in an OR circuit 202 and input to a distribution circuit 1011. That is, in this example, one distribution circuit 1011 is shared by the plurality of pixel circuits 10₁ to 10₄. Note that although the OR circuit 202 is depicted not to be included in the distribution circuit 1011 in FIG. 13B, it is not limited to this example, and the OR circuit 202 may be included in the distribution circuit 1011.

In the example of FIG. 13B, it is based on the premise that each of the pixel circuits 10₁ to 10₄ distributes to four and that the distribution circuit 1011 distributes the output signal Voᵢᵥ integrated by the OR circuit 202 to sixteen paths. The distributed and integrated output signals Voᵢᵥ are input to counters 201₁, 201₂, 201₃, . . . , and 201₁₆ via switch circuits 200₁, 200₂, 200₃, . . . , and 200₁₆, respectively. The open or closed state of the switch circuits ₁, 200₂, 200₃, . . . , and 200₁₆ is controlled by enable signals EN₁, EN₂, EN₃, . . . , and EN₁₆, respectively.

In a case where the plurality of pixel circuits 10₁ to 10₄ is binned to form one pixel, the number of pixels is reduced, and the resolution is reduced. On the other hand, it is possible to increase the number of distributions and the number of counters per pixel (in a case where Hamiltonian encoding is applied to the modulation code, the order k can be increased), and it is possible to perform ranging over a longer distance.

### 2-4. Second Modification of First Embodiment

Next, a second modification of the first embodiment will be described. The second modification of the first embodiment is an example in which only a circuit portion (front end 1010) is shared in binning of a plurality of pixel circuits 10.

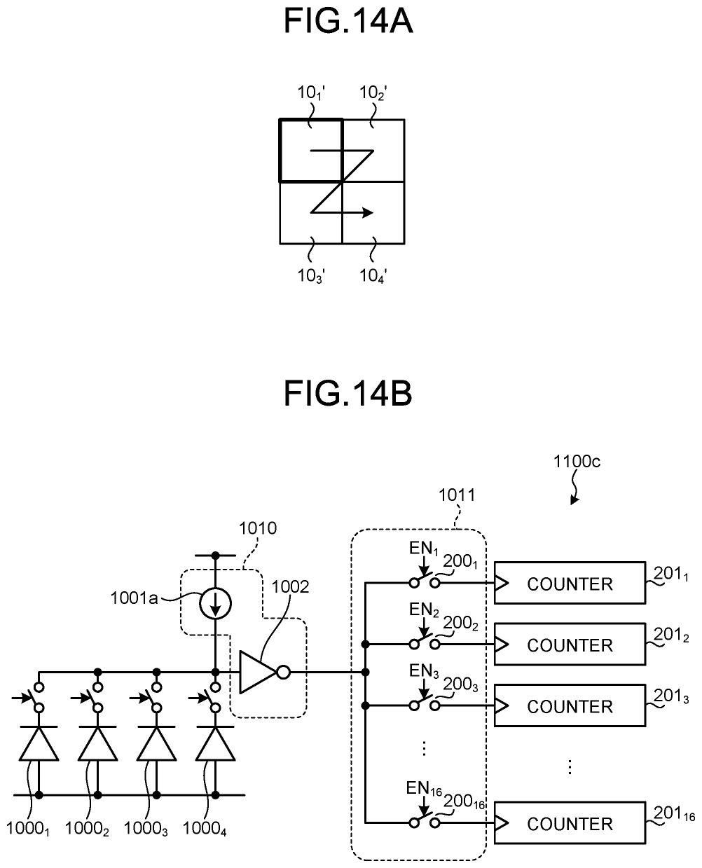

FIGS. 14A and 14B are diagrams for describing binning according to the second modification of the first embodiment. For example, as depicted in FIG. 14A, four pixel circuits 10₁′, 10₂′, 10₃′, and 10₄′ arrayed in a lattice pattern are binned. In this example, as depicted in FIG. 14B, in a light receiving circuit 1100c, one front end 1010 is shared by light receiving elements 1000₁, 1000₂, 1000₃, and 1000₄ included in the respective pixel circuits 10₁′ to 10₄′ by the pixel circuits 10₁′ to 10₄′.

Note that the number of pixel circuits 10′ (light receiving elements 1000) sharing the front end 1010 by binning is not limited to four. Two or three pixel circuits 10′ may be binned, or five or more pixel circuits 10′ may be binned.

The pixel circuits 10₁′ to 10₄′ are switched and scanned in such a manner that the light receiving elements 1000₁ to 1000₄ are sequentially activated, for example, as indicated by an arrow in FIG. 14A. As an example, the light receiving elements 1000₁ to 1000₄ included in the respective pixel circuits 10₁′ to 10₄′ is switched between active and inactive by a switch circuit provided on a cathode side as depicted in FIG. 14B.

In the example of FIG. 14B, it is based on the premise that each of the pixel circuits 10₁′ to 10₄′ distributes to four and that a distribution circuit 1011 distributes an output signal Voᵢᵥ output from an inverter 1002 of the front end 1010 shared by the pixel circuits 10₁′ to 10₄′ to sixteen paths and inputs the output signal Voᵢᵥ to counters 201₁, 201₂, 201₃, . . . , and 201₁₆ via switch circuits 200₁, 200₂, 200₃, . . . , and 200₁₆, respectively. The open or closed state of the switch circuits ₁, 200₂, 200₃, . . . , and 200₁₆ is controlled by enable signals EN₁, EN₂, EN₃, . . . , and EN₁₆, respectively.

In such a configuration, for example, in a case where the pixel circuit 10₁′ is scanned, the switch circuit on the cathode side of the light receiving element 1000₁ is closed, and the output signal Voᵢᵥ is input to the counters 201₁ to 201₄ under the control by the enable signals EN₁ to EN₄. Similarly, in a case where the pixel circuit 101′ is scanned, the switch circuit on the cathode side of the light receiving element 10002 is opened, and the output signal Voᵢᵥ is input to counters 201₅ to 201₈ (not depicted) under the control by the enable signals EN5 to EN8.

As described above, by scanning each of the pixel circuits 10₁′ to 10₄′ while switching the light receiving elements 1000₁ to 1000₄ to be activated, it becomes possible to increase the number of distributions and the number of counters per pixel without reducing the resolution and to perform ranging over a longer distance.

### 2-5. Third Modification of First Embodiment

Next, a third modification of the first embodiment will be described. The third modification of the first embodiment is an example of using a modulation code with a ranging pattern different from Hamiltonian encoding while satisfying the conditions (1) and (2) described above. Note that in the third modification of the first embodiment, the configurations described in the first embodiment and the first and second modifications of the first embodiment can be applied as they are as the circuit configuration and others, and thus description thereof is omitted here.

In the modulation code by the Hamiltonian encoding described above, the duty ratio is not constant particularly in a high-order pattern. In the example of the order k=4 in FIG. 3A, the duty ratio is not constant in the patterns by the enable signals EN₃ and EN₄. Furthermore, in the example of the order k=5 in FIG. 12, the duty ratio is not constant in the patterns of the enable signals EN₂ to EN₅. There is a possibility that control such as timing management is difficult for a signal whose duty ratio is not constant.

In the third modification of the first embodiment, a modulation code including a plurality of patterns is proposed, the modulation patterns satisfying the above-described conditions (1) and (2) and having a constant duty ratio in each of the patterns.

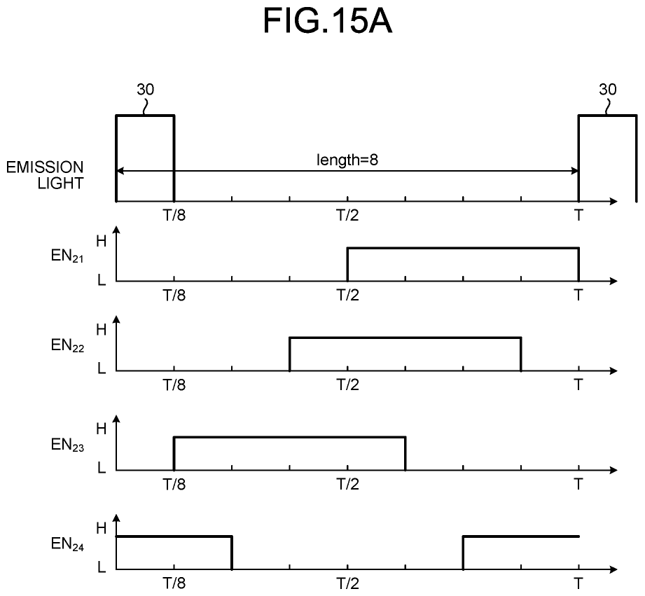

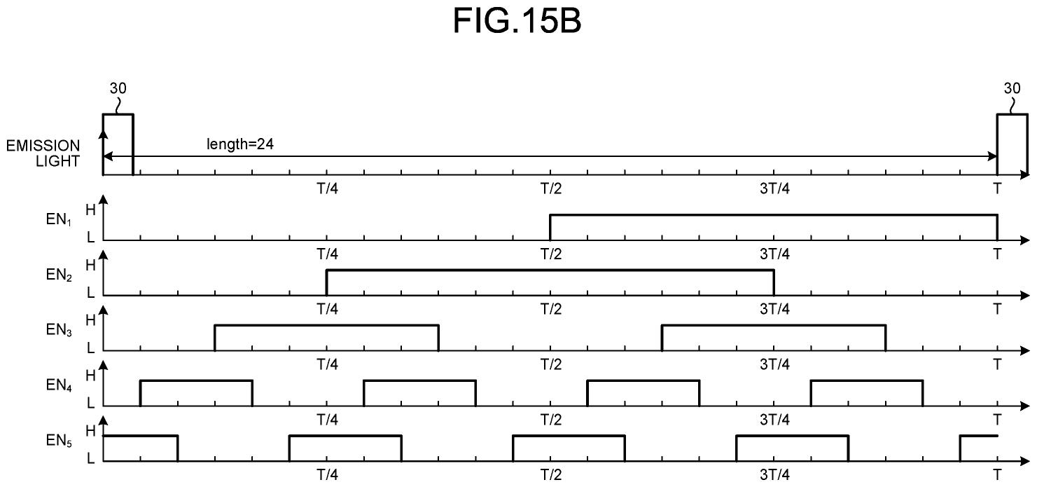

FIGS. 15A and 15B are diagrams depicting examples of modulation patterns according to the third modification of the first embodiment. FIG. 15A depicts an example of modulation patterns of the number of distributions “4” (order k=4), and FIG. 15B depicts an example of the modulation patterns of the number of distributions “5” (order k=5). In these modulation codes, the duty ratio of each of the patterns included in the modulation codes is 50%, and in adjacent patterns, the length of a period in a high state is set in such a manner as to be in a relationship of 1:1 or 1:2. In addition, each period in a high state is configured to have an overlapping portion of at least one unit time between adjacent patterns.

In the case of this modulation code, the return distance length can be calculated by Equations (7) and (8).

length=2^{k-1}(k is even number) (7)

length=3×2^{k-2}(k is an odd number) (8)

According to the Equations (7) and (8), the return distance length in the case of k=4 to 8 is as follows. In this manner, in a case where the modulation code according to the third modification of the first embodiment is applied to the modulation code, the return distance length is doubled or more by increasing the number of distributions by one, and the distance that can be measured can be extended.
k=4:length=8
k=5:length=24
k=6:length=32
k=7:length=96
k=8:length=128

More specifically, in the example of FIG. 15A in which the number of distributions is “4” and the return distance length=8, the enable signal EN₁ is set to a low state in a period of four unit times from the origin, a high state in a period of next four unit times, and the enable signal EN₂ is set to a low state in a period of first three unit times, a high state in a period of next four unit times, and a low state in a period of subsequent one unit time. In addition, the enable signal EN₃ is, in a time series, set to a low state for one unit time, a high state for four unit times, and a low state for three unit times. Furthermore, the enable signal EN₄ is, in a time series, set to a high state for two unit times, a low state for four unit times, and a high state for two unit times.

As described above, in a case where the number of distributions is “4” and the return distance length=8, the enable signals EN₁ to EN₄ each have a duty ratio of 50%.

Meanwhile, in the example of FIG. 15B in which the number of distributions is “5” and the return distance length=24, the enable signal EN₁ is set to a low state in a period of twelve unit times from the origin, a high state in a period of next twelve unit times, and the enable signal EN₂ is set to a low state in a period of first six unit times, a high state in a period of next twelve unit times, and a low state in a period of subsequent six unit times. The enable signal EN3 is set to a low state in a period of first three unit times, a high state in a period of next six unit times, a low state in a period of subsequent six unit times, a high state in a period of subsequent six unit times, and a low state in a period of subsequent three unit times. In addition, the enable signal EN₄ repeats a high state and a low state each for three unit times after a low state for one unit time and is set to a low state for two unit times at the end of the pattern. Furthermore, the enable signal EN₅ repeats a low state and a high state each for three unit times after a high state for two unit times and is set to a high state for one unit time at the end of the pattern.

As described above, in a case where the number of distributions is “5” and the return distance length=24, the enable signals EN₁ to EN₅ each have a duty ratio of 50%.

In the modulation code according to the third modification of the first embodiment, the duty ratio is 50% in all the patterns, and thus control such as timing management is easy as compared with the modulation code by the Hamiltonian encoding described above.

### 3. Second Embodiment of Present Disclosure

Next, a second embodiment of the present disclosure will be described. In the second embodiment, the luminance is detected using an SPAD, and the luminance detection and the ranging are switched or executed in parallel.

### 3-1. Configuration Example According to Second Embodiment

### 3-1-1. Basic Configuration Example of Luminance Detection

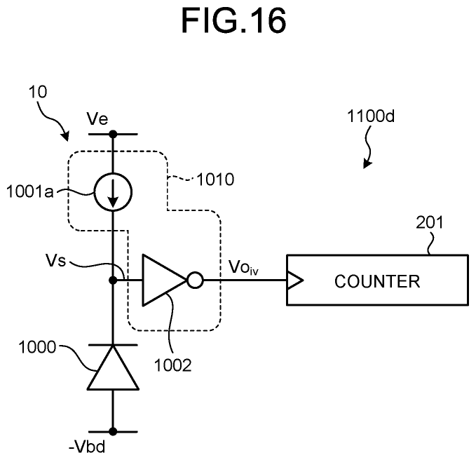

First, a basic configuration example of luminance detection will be described as a configuration example according to the second embodiment. FIG. 16 is a diagram depicting a basic configuration example in a case where luminance is detected using an SPAD. In FIG. 16, in a light receiving circuit 1100d, an output signal Voᵢᵥ output from a pixel circuit 10 is directly input to a counter 201. The counter 201 measures photons incident on a light receiving element 1000 on the basis of the output signal Voᵢᵥ during a predetermined exposure period in one frame, for example.

The number of photons measured by the counter 201 is converted into a luminance signal by a signal processing section 113, for example. By acquiring this luminance signal, for example, from all the pixel circuits 10 included in a pixel array section 101, an image signal for one screen can be obtained. In addition, a moving image can be obtained by executing this luminance detection in each of frames that are temporally continuous.

### 3-1-2. First Configuration Example Using Both Luminance Detection and Ranging

In the above-described basic configuration example, only luminance detection is performed using the SPAD. Next, a first configuration example for using both luminance detection and ranging will be described. The first configuration example is an example of binning a plurality of pixel circuits 10 and a plurality of counters 201 each corresponding to one of the plurality of pixel circuits 10 in the configuration of FIG. 16.

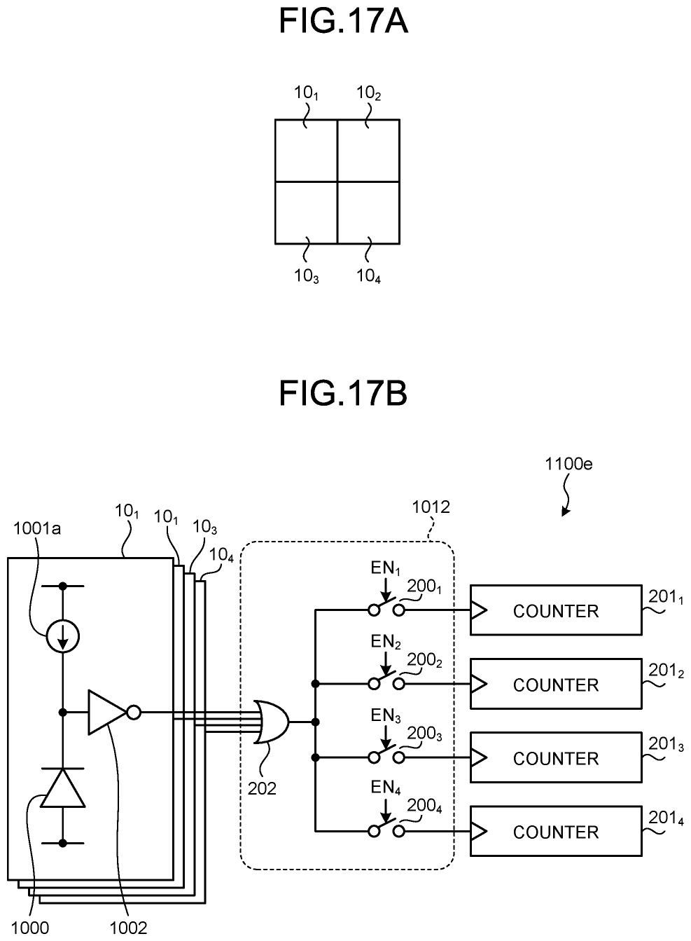

FIGS. 17A and 17B are diagrams for describing a first configuration example in a case where both luminance detection and ranging are used according to the second embodiment (hereinafter referred to as a first configuration example according to the second embodiment). In the first configuration example according to the second embodiment, as depicted in FIG. 17A, four pixel circuits 10₁, 10₂, 10₃, and 10₄ arrayed in a lattice pattern and counters 201₁, 201₂, 201₃, and 201₄ (not depicted) corresponding to the pixel circuits 10₁, 10₂, 10₃, and 10₄, respectively, are binned.

Note that the number of the pixel circuits 10 and the counters 201 to be binned is not limited to four. Two or three pixel circuits 10 may be binned, or five or more pixel circuits 10 may be binned.

FIG. 17B is a diagram depicting an example of a light receiving circuit according to a first configuration example according to the second embodiment. In FIG. 17B, in a light receiving circuit 1100e, an output signal Voᵢᵥ output from each of the four pixel circuits 10₁ to 10₄ is input to a distribution and switching circuit 1012.

The distribution and switching circuit 1012 includes an OR circuit 202 and switch circuits 200₁ to 200₄ whose opening and closing are controlled by enable signals EN₁ to EN₄, respectively. At the time of luminance detection, the distribution and switching circuit 1012 switches the paths so that output signals Voᵢᵥ output from the pixel circuits 10₁ to 10₄ are directly input to the counters 201₁ to 201₄, respectively.

Meanwhile, at the time of ranging, the distribution and switching circuit 1012 integrates the output signals Voᵢᵥ output from the pixel circuits 10₁ to 10₄ by a logical sum in the OR circuit 202. Then, the distribution and switching circuit 1012 inputs the output signal Voᵢᵥ integrated by the OR circuit 202 to the counters 201₁ to 201₄ via the switch circuits 200₁ to 200₄ whose opening and closing are controlled by the enable signals EN₁ to EN₄, respectively.

Note that the enable signals EN₁ to EN₄ for controlling opening and closing of the switch circuits 200₁ to 200₄ may be signals based on the modulation code according to Hamiltonian encoding depicted in FIG. 10 or signals based on the modulation code according to the third modification of the first embodiment depicted in FIG. 15A.

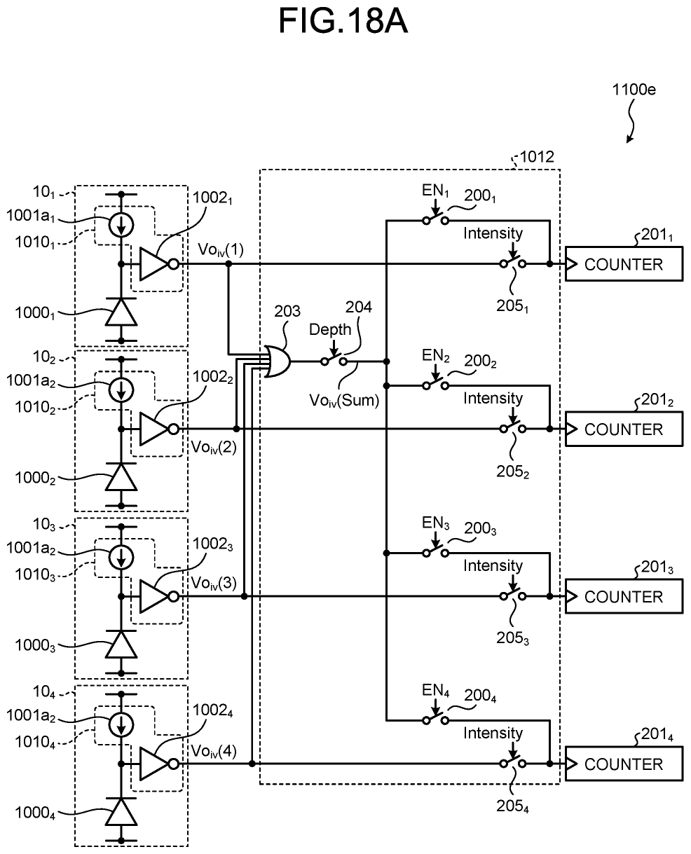

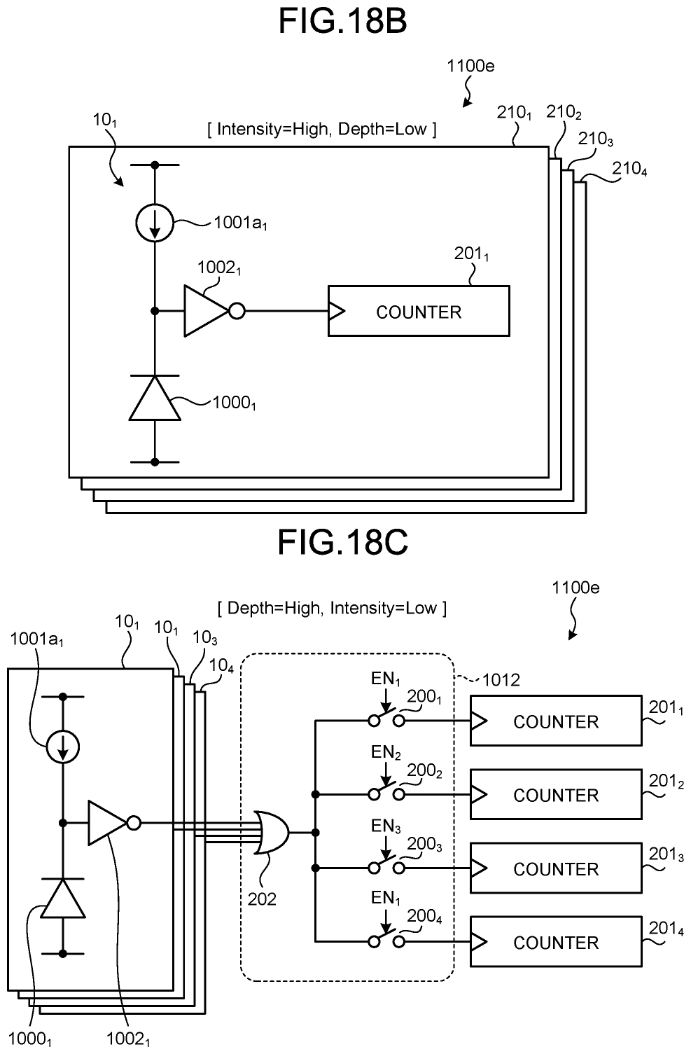

FIGS. 18A, 18B, and 18C are diagrams for more specifically describing the distribution and switching circuit 1012 applicable to the first configuration example of the second embodiment.

FIG. 18A is a diagram depicting a configuration example of the distribution and switching circuit 1012 applicable to the first configuration example of the second embodiment in more detail. In FIG. 18A, the pixel circuit 10₁ includes a light receiving element 1000₁ that is an SPAD and a current source 1001a₁ and an inverter 1002₁ included in a front end 1010₁, similarly to the pixel circuit 10 in FIG. 9 and others. The pixel circuit 10₂ includes a light receiving element 1000₂ and a current source 1001a₂ and an inverter 1002₂ included in a front end 1010₂. The pixel circuit 103 includes a light receiving element 1000₃ and a current source 1001a₃ and an inverter 1002₃ included in a front end 1010₃. Similarly, the pixel circuit 10₄ includes a light receiving element 1000₄ and a current source 1001a₄ and an inverter 1002₄ included in a front end 1010₄.

An output signal Voᵢᵥ(1) output from the pixel circuit 101 is input to an OR circuit 203 and is input to the counter 201₁ via the switch circuit 205₁. Similarly, output signals Voᵢᵥ(2), Voᵢᵥ(3), and Voᵢᵥ(4) output from the pixel circuits 10₂, 10₃, and 10₄, respectively, are input to the OR circuit 203 and input to the counters 201₂, 201₃, and 201₄ via the switch circuits 205₂, 205₃, and 205₄, respectively.

Opening and closing of each of the switch circuits 205₁ to 205₄ are controlled by a signal Intensity. For example, each of the switch circuits 205₁ to 205₄ is controlled to be in a closed state when the signal Intensity is high and to be in an open state when the signal Intensity is low.

A signal (referred to as a signal Voᵢᵥ(Sum)) obtained by integrating the output signals Voᵢᵥ(1) to Voᵢᵥ(4) output from the OR circuit 203 by a logical sum is distributed to four paths via a switch circuit 204 whose opening and closing is controlled by a signal Depth. The signal Voᵢᵥ(Sum) distributed to the four paths is input to the counters 201₁ to 201₄ via the switch circuits 200₁ to 200₄ whose opening and closing are controlled by the enable signals EN₁ to EN₄, respectively.

Note that each of the switch circuits 205₁ to 205₄ is controlled to be in a closed state, for example, when the signal Intensity is high and to be in an open state when the signal Intensity is low. In addition, the switch circuit 204 is controlled to be in a closed state when the signal Depth is high and to be in an open state when the signal Depth is low.

In such a configuration, by setting the signal Intensity to high and the signal Depth to low, as depicted in FIG. 18B, the light receiving circuit 1100e includes four units 210₁ to 210₄ each having a configuration equivalent to the basic configuration for luminance detection described with reference to FIG. 16. In these units 210₁ to 210₄, luminance detection for the pixel circuits 10₁ to 10₄ can be performed on the basis of a measurement result by the counters 201₁ to 201₄, respectively.

On the other hand, in the configuration of FIG. 18A, by setting the signal Depth to high and the signal Intensity to low, as depicted in FIG. 18C, the light receiving circuit 1100e has a configuration in which the pixel circuits 10₁ to 10₄ are binned like in the light receiving circuit 1100e of FIG. 13B described above.

Therefore, also in the configuration of FIG. 18C, similarly to the configuration of FIG. 13B described above, the resolution is reduced due to the decrease in the number of pixels, whereas the ranging over a longer distance is possible.

As described above, according to the first configuration example of the second embodiment, it is possible to switch and execute the luminance detection and the ranging.

### 3-1-3. Second Configuration Example Using Both Luminance Detection and Ranging

Next, a second configuration example for using both luminance detection and ranging according to the second embodiment will be described. The second configuration example is an example in which only counters 201 are binned in the binning of a plurality of pixel circuits 10 according to the second modification of the first embodiment described above.

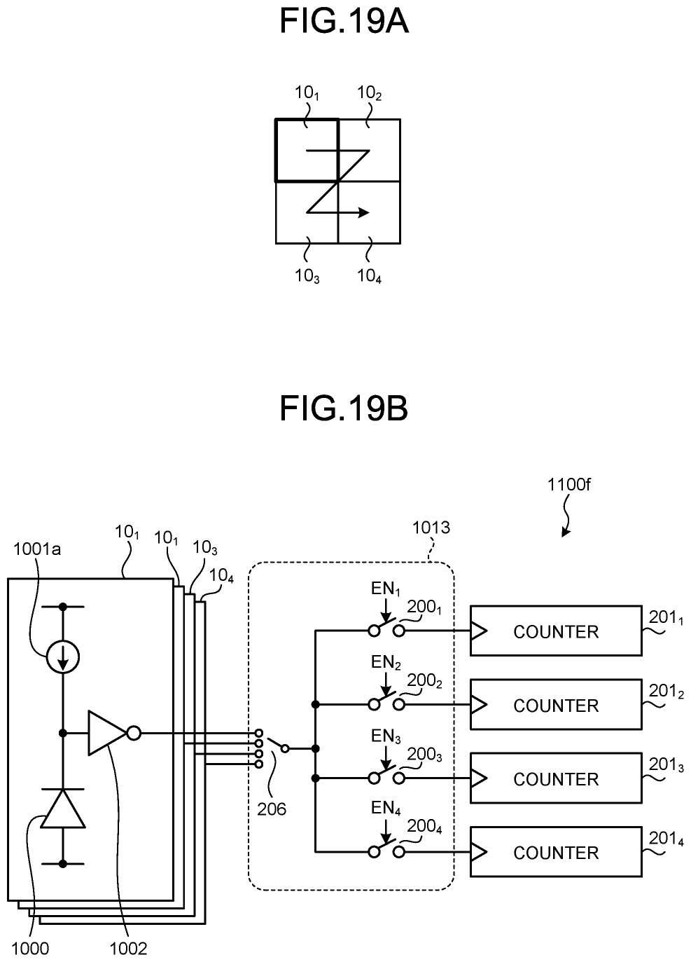

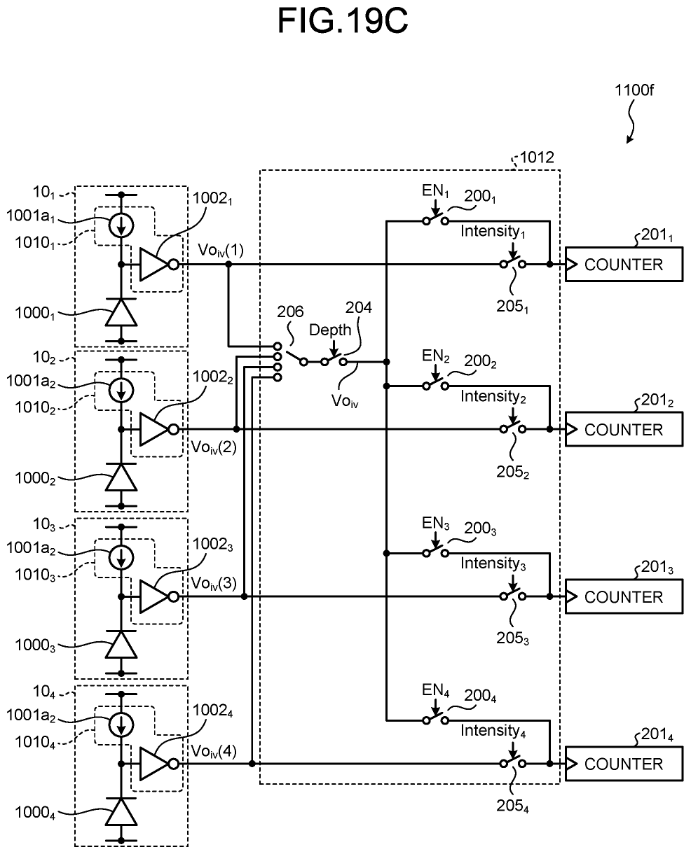

FIGS. 19A, 19B, and 19C are diagrams for describing a second configuration example in a case where both luminance detection and ranging are used according to the second embodiment (hereinafter referred to as the second configuration example according to the second embodiment).

The pixel circuits 10₁ to 10₄ are switched and scanned in such a manner that the pixel circuits 10₁ to 10₄ are sequentially activated, for example, as indicated by an arrow in FIG. 19A. For example, the pixel circuits 10₁ to 10₄ are switched so that respective light receiving elements 1000₁ to 1000₄ are sequentially activated.

FIG. 19B is a diagram depicting an example of a light receiving circuit according to the second configuration example according to the second embodiment. In FIG. 19B, in a light receiving circuit 1100f, an output signal Voᵢᵥ output from each of the four pixel circuits 10₁ to 10₄ is input to a distribution and switching circuit 1013.

The distribution and switching circuit 1013 includes a switch circuit 206 having four selection input terminals and switch circuits 200₁ to 200₄ whose opening and closing are controlled by enable signals EN₁ to EN₄, respectively. Output signals Voᵢᵥ output from the respective pixel circuits 10₁ to 10₄ are input to four selection input terminals of the switch circuit 206.

At the time of luminance detection, the distribution and switching circuit 1013 selects an output signal Voᵢᵥ of an activated pixel circuit among the pixel circuits 10₁ to 10₄ by the switch circuit 206. Then, the distribution and switching circuit 1013 switches paths so that the output signal Voᵢᵥ output from the switch circuit 206 is input to a counter corresponding to a pixel circuit selected by the switch circuit 206 from among the counters 201₁ to 201₄.

On the other hand, at the time of ranging, the distribution and switching circuit 1013 selects the output signal Voᵢᵥ of the activated pixel circuit among the pixel circuits 10₁ to 10₄ by the switch circuit 206. Then, the distribution and switching circuit 1013 distributes the output signal Voᵢᵥ output from the switch circuit 206 to four paths and inputs the signals to the respective counters 201₁ to 201₄ via the switch circuits 200₁ to 200₄ whose opening and closing are controlled by the enable signals EN₁ to EN₄, respectively.

Note that the enable signals EN₁ to EN₄ for controlling opening and closing of the switch circuits 200₁ to 200₄ may be signals based on the modulation code according to Hamiltonian encoding depicted in FIG. 10 or signals based on the modulation code according to the third modification of the first embodiment depicted in FIG. 15A.

FIG. 19C is a diagram depicting a configuration example of the distribution and switching circuit 1013 applicable to the second configuration example of the second embodiment in more detail. Note that the same reference numerals are given to parts shared with those in FIG. 18A described above, and a detailed description thereof will be omitted.

An output signal Voᵢᵥ(1) output from the pixel circuit 10₁ is input to a first selection input terminal of the switch circuit 206 and is input to a counter 201₁ via a switch circuit 205₁. Similarly, output signals Voᵢᵥ(2), Voᵢᵥ(3), and Voᵢᵥ(4) output from the pixel circuits 10₂, 10₃, and 10₄, respectively, are input to second, third, and fourth selection input terminals of the switch circuit 206, respectively, and input to the counters 201₂, 201₃, and 201₄ via the switch circuits 205₂, 205₃, and 205₄, respectively.

Opening and closing of the switch circuits 205₁, 205₂, 205₃, and 205₄ are controlled by signals Intensity₁, Intensity₂, Intensity₃, and Intensity₄. For example, the switch circuit 205₁ is controlled to be in a closed state when the signal Intensity₁ is high and to be in an open state when the signal Intensity₁ is low. The same applies to the other switch circuits 205₂ to 205₄.

In such a configuration, by setting a signal Depth to high and setting the signals Intensity₁ to Intensity₄ to low, ranging becomes possible. In this case, by sequentially selecting the first to fourth selection input terminals of the switch circuit 206, it becomes possible to perform ranging by sequentially scanning the pixel circuits 10₁ to 10₄ depicted in FIG. 19A.

On the other hand, in a case of performing luminance detection, the signal Depth is set to low, the first to fourth selection input terminals of the switch circuit 206 are sequentially selected, and the signal Intensity corresponding to a selected selection input terminal is sequentially set to high in synchronization with selection of the first to fourth selection input terminals of the switch circuit 206 among the signals Intensity₁ to Intensity₄. As a result, it becomes possible to perform luminance detection by sequentially scanning the pixel circuits 10₁ to 10₄ depicted in FIG. 19A.

As described above, by scanning each of the pixel circuits 10₁ to 10₄ while switching the pixel circuits to be activated, it becomes possible to increase the number of distributions and the number of counters per pixel without reducing the resolution and to perform ranging over a longer distance.

Note that in the second configuration example according to the second embodiment, only the front ends 1010 may be binned for the plurality of light receiving elements 1000₁ to 1000₄, similarly to the configuration of FIG. 14B.

### 3-1-4. Third Configuration Example Using Both Luminance Detection and Ranging

Next, a third configuration example using both luminance detection and ranging according to the second embodiment will be described. In the third configuration example, luminance detection and ranging can be simultaneously executed.

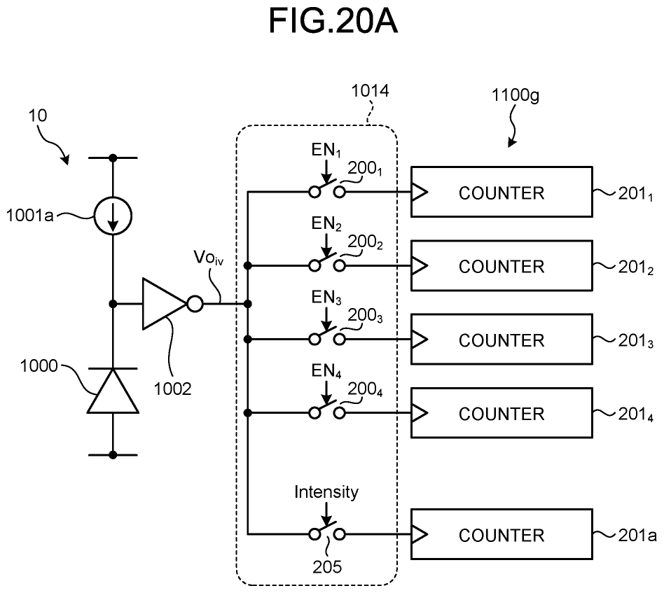

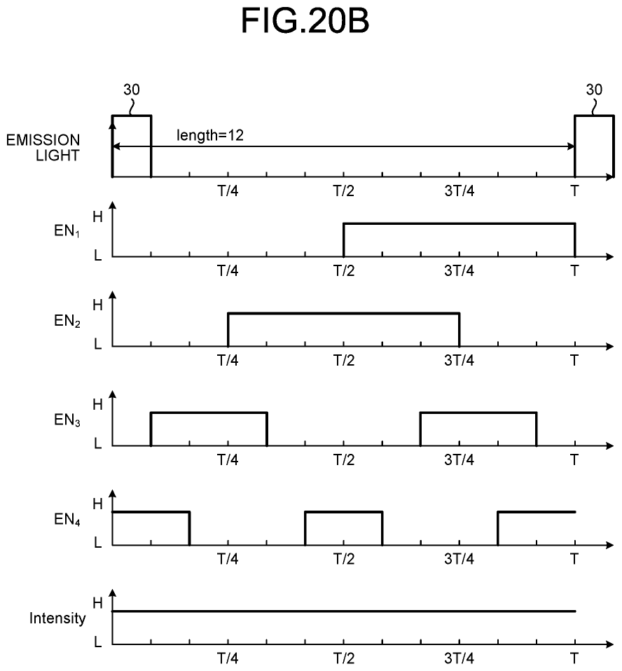

FIG. 20A is a diagram depicting an example of a light receiving circuit according to the third configuration example according to the second embodiment. In the light receiving circuit 1100g depicted in FIG. 20A, a distribution and switching circuit 1014 distributes an output signal Voᵢᵥ output from the pixel circuit 10 to a plurality of paths for ranging and a path for luminance detection.

More specifically, the distribution and switching circuit 1014 distributes the output signal Voᵢᵥ of a pixel circuit 10 to a plurality of paths for input to counters 201₁ to 201₄ via switch circuits 200₁ to 200₄ whose opening and closing are controlled by enable signals EN₁ to EN₄, respectively, for ranging, and also to a path for input to a counter 201a via a switch circuit 205 whose opening and closing is controlled by the signal Intensity for luminance detection.

FIG. 20B is a diagram depicting an example of modulation patterns applicable to the third configuration example according to the second embodiment. In this example, a signal based on the modulation code by Hamiltonian encoding described with reference to FIG. 3A and others is applied as the enable signals EN₁ to EN₄. This is not limited to this example, and a signal based on the modulation code according to the third modification of the first embodiment described with reference to FIG. 15A may be applied, or a signal based on another modulation code may be applied.

In FIG. 20B, the lowermost part depicts an example of the signal Intensity applicable to the third configuration example. As described above, in the third configuration example, the signal Intensity is maintained in the high state regardless of the states of the enable signals EN₁ to EN₄.

For example, a predetermined period within a frame period corresponding to a vertical synchronizing signal for an image is set as an exposure period, and the signal Intensity is set to a high state in the exposure period. The counter 201a counts the number of photons incident on a light receiving element 1000 during the exposure period. Meanwhile, the counters 201₁ to 201₄ counts the number of photons incident on the light receiving element 1000 in a ranging period indicated by the enable signals EN₁ to EN₄.

An output signal Voᵢᵥ from the light receiving element 1000 that is an SPAD can be treated as a digital signal. Therefore, even when a ranging period by each of the enable signals EN₁ to EN₄ overlaps with the exposure period by the signal Intensity, each of the counters 201₁ to 201₄ and the counter 201a can count the number of photons incident on the light receiving element 1000 within each of the periods in parallel, and luminance detection and ranging can be simultaneously executed.

### 4. Third Embodiment of Present Disclosure

Next, a third embodiment of the present disclosure will be described. A third embodiment of the present disclosure relates to a configuration of a device applicable to a ranging device 100 according to the above-described first embodiment and the modifications thereof and the configuration examples of the second embodiment.

### 4-1. First Example of Device Configuration According to Third Embodiment

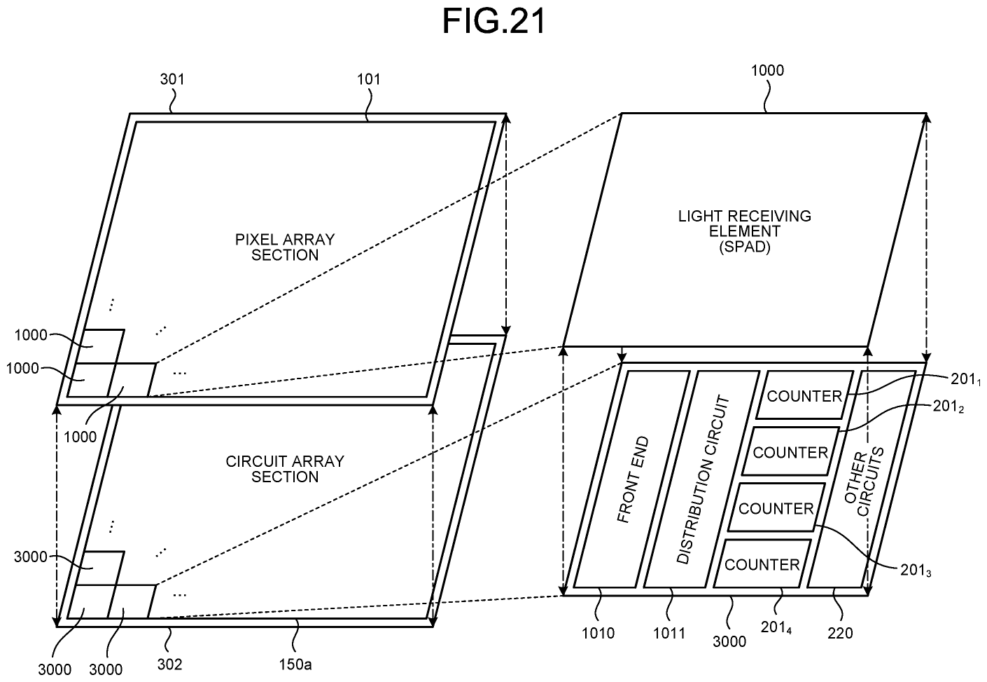

First, a first example of the device configuration according to the third embodiment will be described. FIG. 21 is a schematic diagram depicting the first example of the device configuration according to the third embodiment. In the example of FIG. 21, for example, the circuit configuration depicted in FIG. 9 is presumed.

As depicted on the left side of FIG. 21, a ranging device 100 includes lamination of a light receiving chip 301 and a circuit chip 302, each of which including a semiconductor chip. The light receiving chip 301 and the circuit chip 302 are electrically connected via a connection portion such as a via. The method of connecting the light receiving chip 301 and the circuit chip 302 is not limited to a via, and Cu—Cu connection or a bump can also be applied. Note that in FIG. 21, for the sake of explanation, the light receiving chip 301 and the circuit chip 302 are depicted in a separated state.

In the light receiving chip 301, a pixel array section 101 is disposed. In the region of the pixel array section 101, light receiving elements 1000 respectively included in the plurality of pixel circuits 10 are arranged in an array of a two-dimensional lattice pattern.

In the circuit chip 302, a circuit array section 150a is disposed in correspondence to the pixel array section 101 disposed in the light receiving chip 301. In the circuit array section 150a, a plurality of circuit sections 3000 is arrayed in a two-dimensional lattice pattern corresponding to each of the plurality of light receiving elements 1000 arranged in the pixel array section 101.

The right side of FIG. 21 depicts one light receiving element 1000 and a circuit section 3000 corresponding to the light receiving element 1000 in an enlarged manner. As depicted in the figure, the circuit section 3000 includes a front end 1010, a distribution circuit 1011, counters 201₁ to 201₄, and other circuits 220.

The other circuits 220 can include, for example, the ranging processing section 13, the pixel control section 102, the ranging controlling section 103, the clock generation section 104, the light emission timing controlling section 105, and the I/F 106 depicted in FIG. 6.

In the example on the right side of FIG. 21, the distribution circuit 1011 is disposed adjacent to the front end 1010, and the counters 201₁ to 201₄ are further arranged adjacent to the distribution circuit 1011. As described above, by arranging the front end 1010, the distribution circuit 1011, and the counters 201₁ to 201₄ along the signal flow, it is possible to suppress the influence of noise, signal loss, and the like.

### 4-2. Second Example of Device Configuration According to Third Embodiment

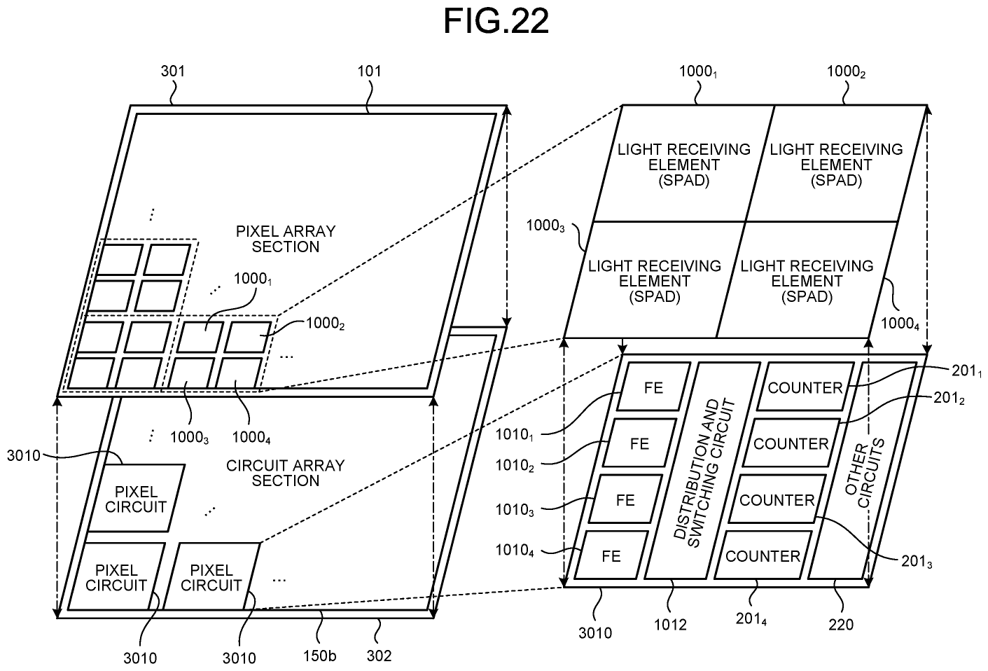

Next, a second example of the device configuration according to the third embodiment will be described. FIG. 22 is a schematic diagram depicting the second example of the device configuration according to the third embodiment. In the example of FIG. 22, for example, the circuit configurations depicted in FIGS. 17A, 17B, and 18A are presumed. Also in the example of FIG. 22, similarly to the configuration of FIG. 21 described above, a ranging device 100 includes lamination of a light receiving chip 301 and a circuit chip 302, each of which including a semiconductor chip.

In the light receiving chip 301, a pixel array section 101 is disposed. In the region of the pixel array section 101, light receiving elements 1000 respectively included in the plurality of pixel circuits 10 are arranged in an array of a two-dimensional lattice pattern. In this example, light receiving elements 1000₁ to 1000₄, arranged in an array of two rows×two columns, and front ends 1010₁ to 1010₄ corresponding thereto are binned.

In the circuit chip 302, a circuit array section 150b is disposed in correspondence to the pixel array section 101 disposed in the light receiving chip 301. In the circuit array section 150b, a plurality of pixel circuits 3010 corresponding to each of sets of light receiving elements 1000₁ to 1000₄ arranged in a 2×2 array in the pixel array section 101 is arranged in an array of a two-dimensional lattice pattern corresponding to the array of the sets of light receiving elements 1000₁ to 1000₄.

The right side of FIG. 22 depicts one set of light receiving elements 1000₁ to 1000₄ and a pixel circuit 3010 corresponding to the set in an enlarged manner. In the pixel circuit 3010, front ends 1010₁ to 1010₄ corresponding to light receiving elements 1000₁ to 1000₄, respectively, a distribution and switching circuit 1012, counters 201₁ to 201₄, and other circuits 220 are arranged.

In the example on the right side of FIG. 22, the distribution circuit 1011 is disposed adjacent to the front ends 1010₁ to 1010₄, and the counters 201₁ to 201₄ are further arranged adjacent to the distribution circuit 1011. As described above, by arranging the front ends 1010₁ to 1010₄, the distribution circuit 1011, and the counters 201₁ to 201₄ along the signal flow, it is possible to suppress the influence of noise, signal loss, and the like.

### 4-3. Third Example of Device Configuration According to Third Embodiment

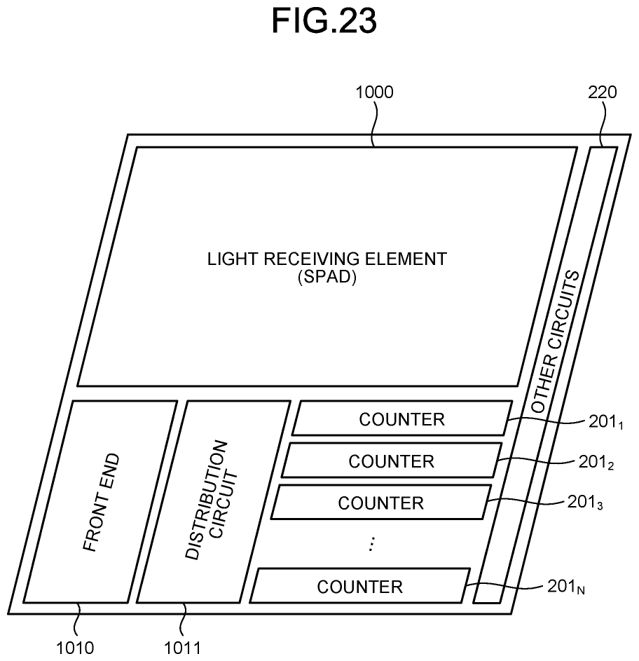

Next, a third example of the device configuration according to the third embodiment will be described. FIG. 23 is a schematic diagram depicting the third example of the device configuration according to the third embodiment. In the first and second examples of the device configuration described above, the ranging device 100 has a structure in which the light receiving chip 301 and the circuit chip 302 are stacked, however, it is not limited to this example. The third example of the device configuration is an example in which a ranging device 100 is configured on one semiconductor chip.

FIG. 23 is a schematic diagram depicting the third example of the device configuration according to the third embodiment. In the example of FIG. 22, for example, the circuit configuration depicted in FIG. 9 is presumed. In FIG. 23, a state is schematically depicted in which one light receiving element 1000, a front end 1010 corresponding to the light receiving element 1000, a distribution circuit 1011, counters 201₁ to 201_{N}, and other circuits 220 are configured on one semiconductor chip. With a plurality of the configurations depicted in FIG. 23 arranged in a two-dimensional lattice pattern, a ranging device 100 including a pixel array section in which the light receiving elements 1000 are arrayed in a two-dimensional lattice pattern is configured.

Note that, in this example, the other circuits 220 are arranged corresponding to the one light receiving element 1000, however, it is not limited to this example. For example, the other circuits 220 can be configured to correspond to the entire pixel array section.

### 5. Fourth Embodiment of Present Disclosure

### 5-1. Application Example of Technology of Present Disclosure

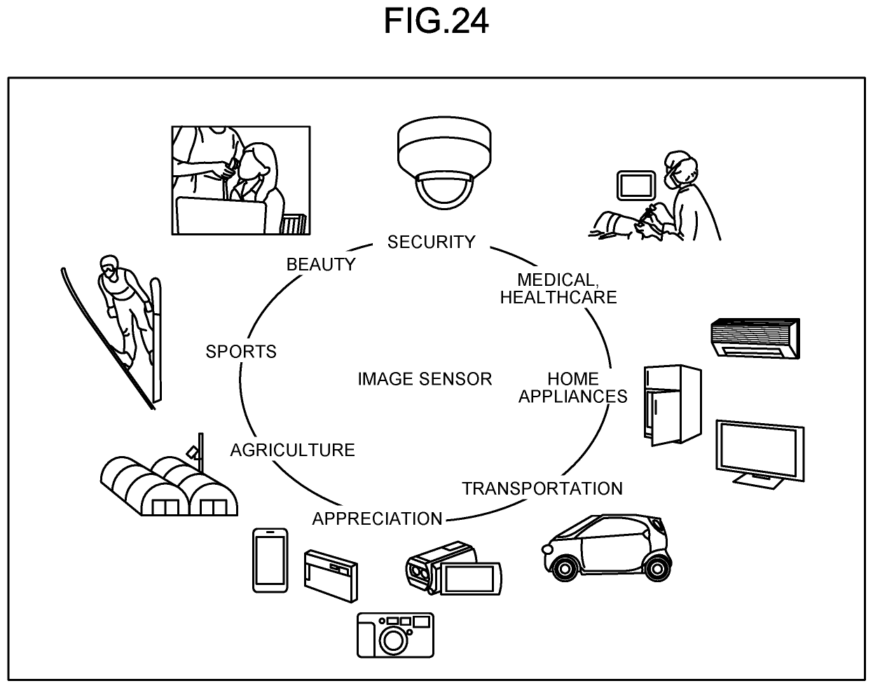

Next, as a fourth embodiment of the present disclosure, application examples of the first embodiment and modifications thereof, the second embodiment, and the third embodiment of the present disclosure will be described. FIG. 24 is a diagram depicting use examples in which a ranging device 100 to which the first embodiment and the modifications thereof, the second embodiment, and the third embodiment can be applied according to the fourth embodiment.

The above-described ranging device 100 can be used in various cases of sensing light such as visible light, infrared light, ultraviolet light, and X-rays as described below.
Devices that capture an image to be used for appreciation such as a digital camera or a portable device with a camera function.
Devices used for transportation such as an in-vehicle sensor that captures images ahead of, in the back of, around, inside, or others of an automobile for safe driving such as automatic stop, recognition of the driver's condition, and others, a monitoring camera that monitors traveling vehicles and roads, and a ranging sensor that measures a distance between vehicles and the like.
Devices used for home appliances such as a TV, a refrigerator, an air conditioner, and others in order to capture an image of a gesture of a user and to operate the device in accordance with the gesture.
Devices used for medical care or health care, such as an endoscope or a device that performs angiography by reception of infrared light.
Devices used for security, such as a monitoring camera for crime prevention or a camera for person authentication.
Devices used for beauty care, such as a skin measuring instrument for photographing skin or a microscope for photographing a scalp.
Devices used for sports, such as an action camera or a wearable camera for sports or the like.
Devices used for agriculture, such as a camera for monitoring conditions of fields or crops.

### 5-2. Application Example to Mobile Body

Next, further application examples of the technology according to the present disclosure will be described. The technology according to the present disclosure may be further implemented to devices mounted on various mobile bodies such as automobiles, electric vehicles, hybrid electric vehicles, motorcycles, bicycles, personal mobilities, airplanes, drones, ships, or robots.

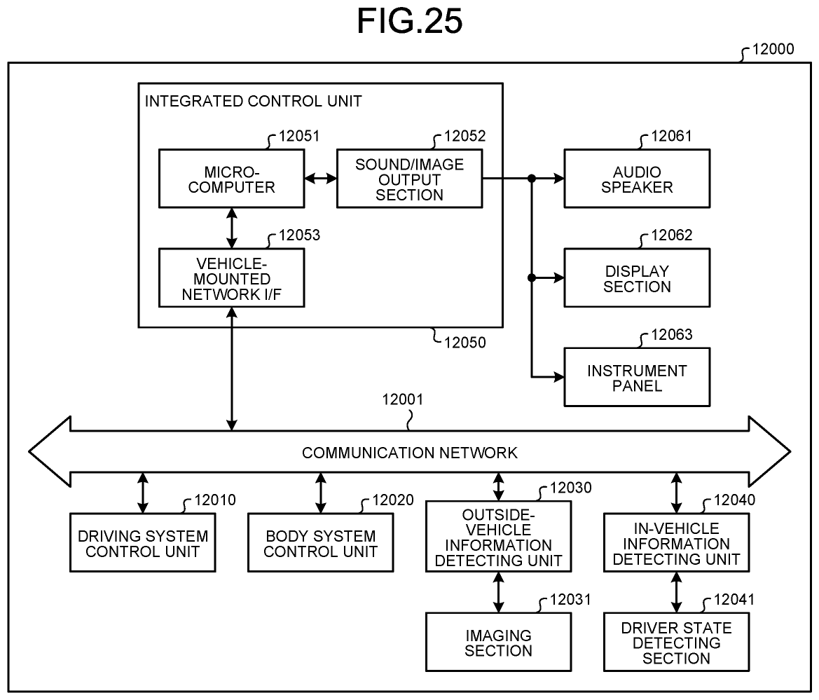

FIG. 25 is a block diagram depicting an example of schematic configuration of a vehicle control system as an example of a mobile body control system to which the technology according to an embodiment of the present disclosure can be applied.

A vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto. For example, the outside-vehicle information detecting unit 12030 performs image processing on the received image and performs object detection processing or distance detection processing on the basis of a result of the image processing.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

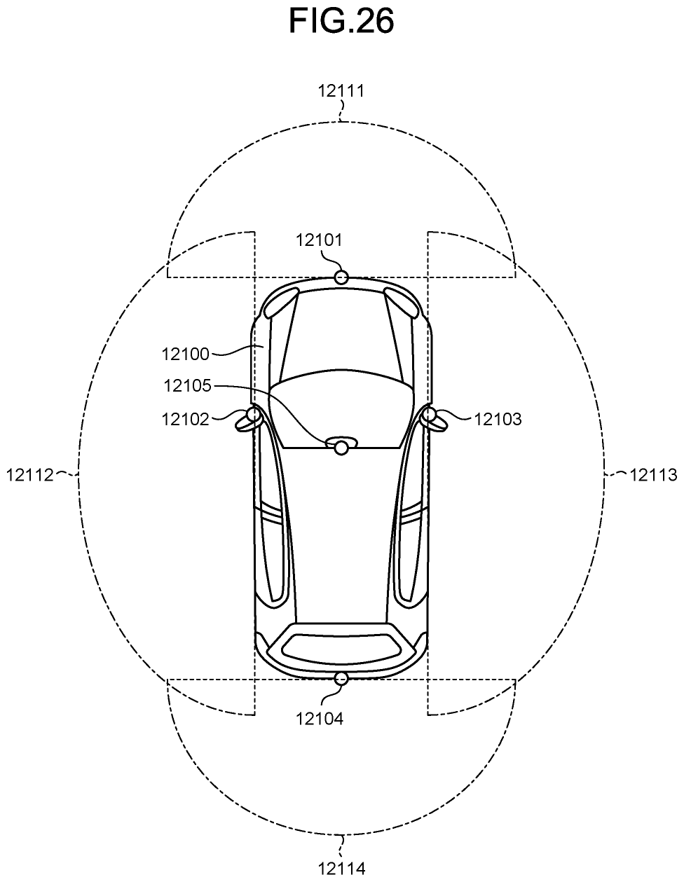

FIG. 26 is a diagram depicting an example of the installation position of the imaging section 12031. In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of a vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 25 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 among the above-described configuration. Specifically, the ranging device 100, to which the above-described first embodiment and the modifications thereof, the second embodiment, and the third embodiment can be applied, can be applied to the imaging section 12031. By applying the technology according to the present disclosure to the imaging section 12031, the distance range of ranging expands, and it becomes possible to facilitate detection of a farther object (such as a preceding vehicle and an obstacle). Furthermore, by applying the configuration of the second embodiment described above to the imaging section 12031, an imaged image can be acquired by the ranging device 100, and thus application as a drive recorder is also possible.

Note that the effects described herein are merely examples and are not limited, and other effects may also be achieved.

Note that the present technology can also have the following configurations.

(1) A light receiving device comprising:
a light receiving element in which avalanche multiplication occurs in response to a photon incident in a state of being charged to a predetermined potential to cause a current to flow, the light receiving element returning to the state by a recharge current;
a current source that supplies the recharge current;
a detection section that detects a voltage based on the current, inverts an output signal in a case where a voltage value of the detected voltage exceeds a threshold value, shapes the inverted output signal into a pulse signal, and outputs the pulse signal;
a plurality of counters that each count the pulse signal output from the detection section; and
a distribution section that selects a target counter to which the pulse signal is to be supplied from among the plurality of counters,
wherein the distribution section selects
the target counter by a plurality of control signals corresponding to the plurality of counters on a one-to-one basis, the plurality of control signals including a state of simultaneously selecting two or more counters among the plurality of counters.
   (2) The light receiving device according to the above (1),
wherein the distribution section excludes
a state in which all of the plurality of counters are selected as the target counter and a state in which none of the plurality of counters is selected as the target counter and selects the target counter by the plurality of control signals that transitions every unit time so that a state of adjacent unit times have a Hamming distance of 1.
   (3) The light receiving device according to the above (2),
wherein the distribution section selects
the target counter by the plurality of control signals each having a duty ratio of 50%.
   (4) The light receiving device according to the above (2),
wherein the distribution section selects
the target counter by the plurality of control signals including a control signal having a duty ratio different from 50%.
   (5) The light receiving device according to any one of the above (1) to (4),
wherein the distribution section is shared by a plurality of pixel circuits each comprising the light receiving element, the current source, and the detection section.
   (6) The light receiving device according to the above (5),
wherein the distribution section selects
the target counter that supplies a respective logical sum of the pulse signals output from the detection sections of the plurality of pixel circuits.
   (7) The light receiving device according to the above (5),
wherein each of the plurality of pixel circuits is sequentially activated, and
the distribution section is input with the pulse signal output from the detection section of the activated pixel circuit among the plurality of pixel circuits.
   (8) The light receiving device according to the above (7),
wherein the current source and the detection section are shared by the plurality of pixel circuits.
   (9) The light receiving device according to the above (6),
wherein the distribution section switches
between supplying the logical sum to the target counter and supplying the pulse signals respectively output from the plurality of pixel circuits to the plurality of counters corresponding the plurality of pixel circuits on a one-to-one basis, respectively.
   (10) The light receiving device according to the above (7),
wherein the distribution section switches between supplying the pulse signal output from the detection section of the activated pixel circuit to the target counter and supplying the pulse signal to a counter corresponding to the activated pixel circuit among the plurality of counters.
   (11) The light receiving device according to any one of the above (1) to (4), further comprising:
another counter that is in a selected state in a predetermined exposure period regardless of the plurality of control signals in addition to the plurality of counters.
   (12) A control method of a light receiving device, the method comprising the steps of:
a detection step, in which avalanche multiplication occurs in response to a photon incident in a state of being charged to a predetermined potential to cause a current to flow, the detection step comprising: detecting a voltage based on the current of a light receiving element that returns to the state by a recharge current supplied from a current source; inverting an output signal in a case where a voltage value of the detected voltage exceeds a threshold value; shaping the inverted output signal into a pulse signal; and outputting the pulse signal from a detection section;
a counting step of counting the pulse signal output from the detection section by each of a plurality of counters; and
a distribution step of selecting a target counter to which the pulse signal is to be supplied from among the plurality of counters,
wherein, in the distribution step,
the target counter is selected by a plurality of control signals corresponding to the plurality of counters on a one-to-one basis, the plurality of control signals including a state of simultaneously selecting two or more counters among the plurality of counters.
   (13) A ranging system comprising:
a light source device comprising a light emitting element that emits light;
a light receiving device comprising a light receiving element that receives light; and
a ranging processing section that performs ranging on a measurement object on the basis of light emitted from the light source device and light received by the light receiving device,
wherein the light receiving device comprises:
the light receiving element in which avalanche multiplication occurs in response to a photon incident in a state of being charged to a predetermined potential to cause a current to flow, the light receiving element returning to the state by a recharge current;
a current source that supplies the recharge current;
a detection section that detects a voltage based on the current, inverts an output signal in a case where a voltage value of the detected voltage exceeds a threshold value, shapes the inverted output signal into a pulse signal, and outputs the pulse signal;
a plurality of counters that each count the pulse signal output from the detection section; and
a distribution section that selects a target counter to which the pulse signal is to be supplied from among the plurality of counters,
the distribution section selects
the target counter by the plurality of control signals corresponding to the plurality of counters on a one-to-one basis, the plurality of control signals including a state of simultaneously selecting two or more counters among the plurality of counters, and
the ranging processing section performs
the ranging on the basis of a counting result obtained by counting the pulse signal by the plurality of counters.

### REFERENCE SIGNS LIST

1 ELECTRONIC DEVICE
10, 10₁, 10₂, 10₃, 10₄ PIXEL CIRCUIT
11 LIGHT SOURCE SECTION
12 LIGHT RECEIVING SECTION
13 RANGING PROCESSING SECTION
14 TOTAL CONTROL SECTION
30 EMISSION LIGHT
32 REFLECTION LIGHT
100 RANGING DEVICE
101 PIXEL ARRAY SECTION
200₁, 200₂, 200₃, 200₄, 200_{N}, 204, 205, 205₁, 205₂, 205₃, 205₄, 206 SWITCH CIRCUIT
201₁, 201₂, 201₃, 201₄, 201₁₆, 201a, 201_{N} COUNTER
202 OR CIRCUIT
301 LIGHT RECEIVING CHIP
302 CIRCUIT CHIP
1000, 1000₁, 1000₂, 1000₃, 1000₄ LIGHT RECEIVING ELEMENT
1001 TRANSISTOR
1001a, 1001a₁, 1001a₂, 1001a₃, 1001a₄ CURRENT SOURCE
1002, 1002₁, 1002₂, 1002₃, 1002₄ INVERTER
1010, 1010₁, 1010₂, 1010₃, 1010₄ FRONT END
1011 DISTRIBUTION CIRCUIT
1012, 1013, 1014 DISTRIBUTION AND SWITCHING CIRCUIT
1100a, 1100b, 1100c, 1100e, 1100f, 1100g LIGHT RECEIVING CIRCUIT

1. A light receiving device comprising:
a light receiving element in which avalanche multiplication occurs in response to a photon incident in a state of being charged to a predetermined potential to cause a current to flow, the light receiving element returning to the state by a recharge current;
a current source that supplies the recharge current;
a detection section that detects a voltage based on the current, inverts an output signal in a case where a voltage value of the detected voltage exceeds a threshold value, shapes the inverted output signal into a pulse signal, and outputs the pulse signal;
a plurality of counters that each count the pulse signal output from the detection section; and
a distribution section that selects a target counter to which the pulse signal is to be supplied from among the plurality of counters,
wherein the distribution section selects
the target counter by a plurality of control signals corresponding to the plurality of counters on a one-to-one basis, the plurality of control signals including a state of simultaneously selecting two or more counters among the plurality of counters.

2. The light receiving device according to claim 1,
wherein the distribution section excludes
a state in which all of the plurality of counters are selected as the target counter and a state in which none of the plurality of counters is selected as the target counter and selects the target counter by the plurality of control signals that transitions every unit time so that a state of adjacent unit times have a Hamming distance of 1.

3. The light receiving device according to claim 2,
wherein the distribution section selects
the target counter by the plurality of control signals each having a duty ratio of 50%.

4. The light receiving device according to claim 2,
wherein the distribution section selects
the target counter by the plurality of control signals including a control signal having a duty ratio different from 50%.

5. The light receiving device according to claim 1,
wherein the distribution section is shared by a plurality of pixel circuits each comprising the light receiving element, the current source, and the detection section.

6. The light receiving device according to claim 5,
wherein the distribution section selects
the target counter that supplies a respective logical sum of the pulse signals output from the detection sections of the plurality of pixel circuits.

7. The light receiving device according to claim 5,
wherein each of the plurality of pixel circuits is sequentially activated, and
the distribution section is input with the pulse signal output from the detection section of the activated pixel circuit among the plurality of pixel circuits.

8. The light receiving device according to claim 7,
wherein the current source and the detection section are shared by the plurality of pixel circuits.

9. The light receiving device according to claim 6,
wherein the distribution section switches
between supplying the logical sum to the target counter and supplying the pulse signals respectively output from the plurality of pixel circuits to the plurality of counters corresponding the plurality of pixel circuits on a one-to-one basis, respectively.

10. The light receiving device according to claim 7,
wherein the distribution section switches between supplying the pulse signal output from the detection section of the activated pixel circuit to the target counter and supplying the pulse signal to a counter corresponding to the activated pixel circuit among the plurality of counters.

11. The light receiving device according to claim 1, further comprising:
another counter that is in a selected state in a predetermined exposure period regardless of the plurality of control signals in addition to the plurality of counters.

12. A control method of a light receiving device, the method comprising the steps of:
a detection step, in which avalanche multiplication occurs in response to a photon incident in a state of being charged to a predetermined potential to cause a current to flow, the detection step comprising: detecting a voltage based on the current of a light receiving element that returns to the state by a recharge current supplied from a current source; inverting an output signal in a case where a voltage value of the detected voltage exceeds a threshold value; shaping the inverted output signal into a pulse signal; and outputting the pulse signal from a detection section;
a counting step of counting the pulse signal output from the detection section by each of a plurality of counters; and
a distribution step of selecting a target counter to which the pulse signal is to be supplied from among the plurality of counters,
wherein, in the distribution step,
the target counter is selected by a plurality of control signals corresponding to the plurality of counters on a one-to-one basis, the plurality of control signals including a state of simultaneously selecting two or more counters among the plurality of counters.

13. A ranging system comprising:
a light source device comprising a light emitting element that emits light;
a light receiving device comprising a light receiving element that receives light; and
a ranging processing section that performs ranging on a measurement object on the basis of light emitted from the light source device and light received by the light receiving device,
wherein the light receiving device comprises:
the light receiving element in which avalanche multiplication occurs in response to a photon incident in a state of being charged to a predetermined potential to cause a current to flow, the light receiving element returning to the state by a recharge current;
a current source that supplies the recharge current;
a detection section that detects a voltage based on the current, inverts an output signal in a case where a voltage value of the detected voltage exceeds a threshold value, shapes the inverted output signal into a pulse signal, and outputs the pulse signal;
a plurality of counters that each count the pulse signal output from the detection section; and
a distribution section that selects a target counter to which the pulse signal is to be supplied from among the plurality of counters,
the distribution section selects
the target counter by the plurality of control signals corresponding to the plurality of counters on a one-to-one basis, the plurality of control signals including a state of simultaneously selecting two or more counters among the plurality of counters, and
the ranging processing section performs
the ranging on the basis of a counting result obtained by counting the pulse signal by the plurality of counters.
